(19) United States
(12) Patent Application Publication
(10) Pub. No.: US 2013/0001796 A1
(43) Pub. Date: Jan. 3, 2013

(54) SEMICONDUCTOR DEVICE

(76) Inventors: Ju-Hak SONG, Hwasung-City (KR); Tae-Hwan YUN, Hwasung-City (KR); Woo-Sung YANG, Hwasung-City (KR); Jin-Sung LEE, Hwasung-City (KR)

(21) Appl. No.: 13/480,670

(22) Filed: May 25, 2012

(30) Foreign Application Priority Data
Jul. 1, 2011 (KR) 10-2011-0065692

(51) Int. Cl. H01L 23/528

(52) U.S. Cl. 257/774; 257/E23.151

(57) ABSTRACT

A semiconductor device including a plug; a lower insulating film surrounding a lower sidewall of the plug; a spacer surrounding an upper sidewall of the plug; and a first interconnection line on the plug, the lower insulating film, and the spacer, the first interconnection line being in contact with an upper surface of the plug, wherein an upper portion of the spacer protrudes higher than the upper surface of the plug.

### CROSS-REFERENCE TO RELATED APPLICATION

This application claims priority under 35 U.S.C. §119 to Korean Patent Application No. 10-2011-0065692 filed on Jul. 1, 2011, the disclosure of which is hereby incorporated by reference in its entirety.

### BACKGROUND

1. Field

Embodiments relate to a semiconductor device.

2. Description of Related Art

Semiconductor devices may be fabricated by disposing plugs and interconnection lines on a semiconductor substrate.

### SUMMARY

Embodiments are directed to a semiconductor device.

The embodiments may be realized by providing a semiconductor device including a plug; a lower insulating film surrounding a lower sidewall of the plug; a spacer surrounding an upper sidewall of the plug; and a first interconnection line on the plug, the lower insulating film, and the spacer, the first interconnection line being in contact with an upper surface of the plug, wherein an upper portion of the spacer protrudes higher than the upper surface of the plug.

The lower insulating film may be below the spacer, the lower insulating film including a first upper surface lower than the upper surface of the plug.

The lower insulating film may be aligned with a sidewall of the spacer, the lower insulating film including a second upper surface lower than the first upper surface.

The first interconnection line may include a first lower surface on the plug, the first lower surface being lower than an uppermost surface of the plug.

The first lower surface of the first interconnection line may be higher than the second upper surface of the lower insulating film.

The first interconnection line may include a second lower surface lower than the first lower surface thereof, the second lower surface being on the second upper surface of the lower insulating film.

The semiconductor device may further include a second interconnection line at an exterior of the spacer, the second interconnection line extending horizontally in parallel with the first interconnection line.

The second interconnection line may be in contact with the spacer.

The second interconnection line may include a lower surface, the lower surface of the second interconnection line being lower than the second upper surface of the lower insulating film.

The plug may have a vertically extending pillar shape, and the first interconnection line may have a horizontally extending line shape.

The spacer may have a ring shape when viewed in a plan view.

The first interconnection line may be in contact with an upper portion of the spacer and intersects the spacer.

The spacer may include a lower spacer sidewall in contact with the plug, and an upper spacer sidewall not contacting the plug.

The embodiments may also be realized by providing a semiconductor device including a plug; a lower insulating film covering a lower sidewall of the plug; a spacer covering an upper sidewall of the plug; and an interconnection line on the plug, the lower insulating film, and the spacer, wherein the interconnection line includes a first boundary surface, a second boundary surface, and a third boundary surface at a lower surface thereof, the first boundary surface is at an interface of an upper portion of the spacer and the lower surface of the interconnection line, the second boundary surface is at an interface of an upper surface of the plug and the lower surface of the interconnection line, the third boundary surface is at an interface of an upper surface of the lower insulating film and the lower surface of the interconnection line, the first boundary surface is higher than the second boundary surface, and the second boundary surface is higher than the third boundary surface.

The semiconductor device may further include a fourth boundary surface at an interface of a lower surface of the spacer and the upper surface of the lower insulating film, the fourth boundary surface being lower than the second boundary surface and higher than the third boundary surface.

The embodiments may also be realized by providing a semiconductor device including a plug having a lower sidewall and an upper sidewall; a lower insulating film surrounding the lower sidewall of the plug; a spacer surrounding the upper sidewall of the plug; and a first interconnection line on the plug, the lower insulating film, and the spacer, the first interconnection line being in contact with a surface of the plug, wherein an uppermost portion of the spacer protrudes higher than an uppermost surface of the plug, the first interconnection line has a first lower surface on the plug, the lower insulating film has a first upper surface on a lower spacer surface of the spacer, and a plane of the first lower surface is between a plane of the first upper surface of the lower insulating film and a plane of the uppermost surface of the plug.

The lower insulating film may be aligned with a sidewall of the spacer, the lower insulating film including a second upper surface lower than the first upper surface.

The semiconductor device may further include a second interconnection line at an exterior of the spacer, the second interconnection line extending horizontally in parallel with the first interconnection line.

The second interconnection line may include a lower second interconnection line surface, a plane of the lower second interconnection line surface being lower than a plane of the second upper surface of the lower insulating film.

### BRIEF DESCRIPTION OF THE DRAWINGS

Features will become apparent to those of ordinary skill in the art by describing in detail exemplary embodiments with reference to the attached drawings in which:

FIG. 1A illustrates a top view or a plan view of a semiconductor device according to an embodiment.

FIGS. 1B to 1D illustrate longitudinal sectional views of the semiconductor device taken along lines I-I′, II-II′, and III-III′ of FIG. 1A.

FIG. 2A illustrates a top view or a plan view of a semiconductor device according to an embodiment.

FIGS. 2B to 2D illustrate longitudinal sectional views of the semiconductor device taken along lines IV-IV′, V-V′, and VI-VI′ of FIG. 2A.

FIG. 3A illustrates a top view or a plan view of a semiconductor device according to an embodiment.

FIGS. 3B to 3D illustrate longitudinal sectional views of the semiconductor device taken along lines VII-VII′, VIII-VIII′, and IX-IX′ of FIG. 3A.

FIG. 4A illustrates a top view or a plan view of a semiconductor device according to an embodiment.

FIGS. 4B and 4C illustrate longitudinal sectional views of the semiconductor device taken along lines X-X′, and XI-XI′ of FIG. 4A.

FIGS. 5A to 5I, and 5M to 5T illustrate longitudinal sectional views showing stages in a method of forming a semiconductor device taken along line I-I′ of FIG. 1A according to an embodiment.

FIGS. 5J to 5L illustrate longitudinal sectional views showing stages in a method of forming a semiconductor device taken along lines IT, II-II′, and III-III′ of FIG. 1A.

FIGS. 6A, 6B, and 6F illustrate longitudinal sectional views showing stages in a method of forming a semiconductor device taken along line IV-IV′ of FIG. 2A according to an embodiment.

FIGS. 6C to 6E illustrate longitudinal sectional views showing stages in a method of forming a semiconductor device taken along lines IV-IV′, V-V′, and VI-VI′ of FIG. 2A according to an embodiment.

FIGS. 7A, 7B and 7F illustrate longitudinal sectional views showing stages in a method of forming a semiconductor device taken along line VII-VII′ of FIG. 3A according to an embodiment.

FIGS. 7C to 7E illustrate longitudinal sectional views showing stages in a method of forming a semiconductor device taken along lines VII-VII′, VIII-VIII′, and IX-IX′ of FIG. 3A according to an embodiment.

FIGS. 8A, 8B and 8E illustrate longitudinal sectional views showing stages in a method of forming a semiconductor device taken along line X-X′ of FIG. 4A according to an embodiment.

FIGS. 8C and 8D illustrate longitudinal sectional views showing stages in a method of forming a semiconductor device taken along lines X-X′, and XI-XI′ of FIG. 4A according to an embodiment.

FIGS. 9A to 9D illustrate longitudinal sectional views of semiconductor devices according to various embodiments.

FIG. 10 illustrates an electronic system including a semiconductor device according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” with another element, it can be directly connected, or coupled, with the other element or intervening elements may be present. In contrast, if an element is referred to as being “directly connected” or “directly coupled” with another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to top views or plan views that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, a buried region formed by implantation may result in some implantation in the region between the buried region and the surface through which the implantation may take place. Thus, the regions illustrated in the figures are schematic in nature and their shapes do not necessarily illustrate the actual shape of a region of a device, and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

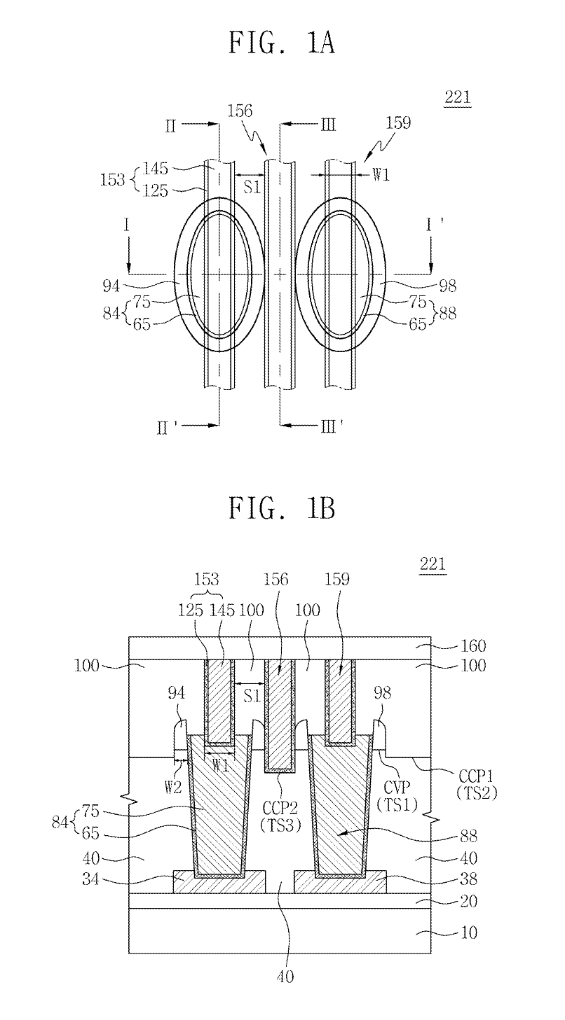

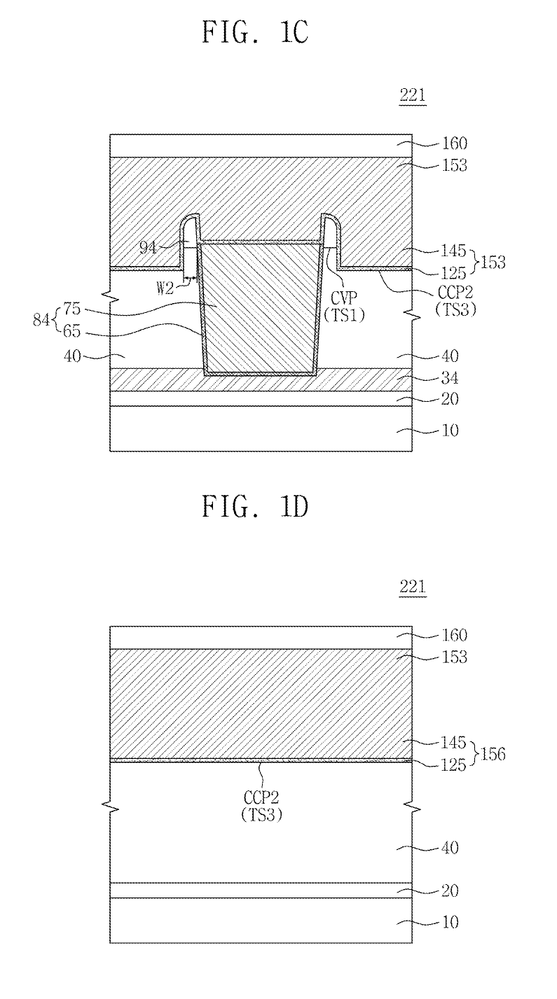

FIG. 1A illustrates a top view or a plan view of a semiconductor device according to an embodiment. FIGS. 1B to 1D illustrate longitudinal sectional views of the semiconductor device taken along lines I-I′, II-II′, and III-III′ of FIG. 1A.

Referring to FIGS. 1A to 1D, a semiconductor device 221 according to an embodiment may include first to third interconnection lines 153, 156, and 159. The first to third interconnection lines 153, 156, and 159 may be horizontally in parallel with an upper surface of a semiconductor substrate 10. The first to third interconnection lines 153, 156, and 159 may extend in a horizontal direction.

The first to third interconnection lines 153, 156, and 159 may be spaced apart from each other by a predetermined distance S1. Each of the first to third interconnection lines 153, 156, and 159 may have a predetermined width W1. The first to third interconnection lines 153, 156, and 159 may include a data-transferring line. Each of the first to third interconnection lines 153, 156, and 159 may include a barrier pattern 125 and a conductive pattern 145.

The barrier pattern 125 may include a metal nitride and/or metallic materials. The metal nitride or metallic material may include at least one of tantalum, tantalum nitride, titanium, titanium nitride, tungsten nitride, or the like. The conductive pattern 145 may include copper. The semiconductor device 221 may include a first plug 84 and a second plug 88. The first plug 84 and the second plug 88 may be in an overlapping relationship with the first interconnection line 153 and the third interconnection line 159, respectively.

In an implementation, the second interconnection line 156 may be disposed between the first plug 84 and the second plug 88. The first plug 84 or the second plug 88 may intersect the first interconnection line 153 or the third interconnection line 159 at side portions thereof facing each other. Upper surfaces of the first plug 84 and the second plug 88 may have a circular shape or an elliptical shape.

The first plug 84 and the second plug 88 may be electrically connected to the first interconnection line 153 and the third interconnection line 159, respectively. The first plug 84 and the second plug 88 may each include a diffusion barrier pattern 65 and a conductive material pattern 75. The diffusion barrier pattern 65 may include at least one of, e.g., tantalum, tantalum nitride, titanium, titanium nitride, and tungsten nitride. The conductive material pattern 75 may include a metal, e.g., tungsten.

A first spacer 94 and a second spacer 98 may be disposed around the first plug 84 and the second plug 88, respectively. The first spacer 94 and the second spacer 98 may surround upper portions of the first plug 84 and the second plug 88, respectively. The first spacer 94 or the second spacer 98 may intersect the first interconnection line 153 or the second interconnection line 159 at side portions thereof facing each other.

The first spacer 94 and the second spacer 98 may each be in contact with the second interconnection line 156. The first spacer 94 and the second spacer 98 may have a ring shape or a doughnut shape. The first spacer 94 may electrically insulate the first plug 84 and the second interconnection line 156. The second spacer 98 may electrically insulate the second plug 88 and the second interconnection line 156.

The first spacer 94 and the second spacer 98 may each include an insulating material. For example, the first spacer 94 and the second spacer 98 may each include silicon nitride and/or silicon oxynitride.

Referring to FIGS. 1B to 1D, the semiconductor device 221 may include a semiconductor substrate 10. The semiconductor substrate 10 may include transistors and/or data storage patterns. The semiconductor substrate 10 may be a single crystalline silicon substrate or a silicon-on-insulator (SOI) substrate.

A material film 20 may be disposed on the semiconductor substrate 10. The material film 20 may include an insulating material. For example, the material film 20 may include silicon oxide or silicon nitride. A first landing pattern 34 and a second landing pattern 38 may be disposed on the material film 20. The first landing pattern 34 and the second landing pattern 38 may have a pad shape or a line shape. The second landing pattern 38 may be the same shape as or a different shape than the first landing pattern 34.

The first landing pattern 34 and the second landing pattern 38 may be a portion of the transistors and/or the data storage patterns. The first landing pattern 34 and the second landing pattern 38 may include conductive materials. The first plug 84 and the second plug 88 may be disposed on the first landing pattern 34 and the second landing pattern 38, respectively. For example, the first plug 84 and the second plug 88 may be in contact with the first landing pattern 34 and the second landing pattern 38, respectively.

Lower surfaces of the first plug 84 and/or the second plug 88 may be lower than uppermost surfaces of the first landing pattern 34 and/or the second landing pattern 38. As noted above, the first plug 84 and the second plug 88 may each include the diffusion barrier pattern 65 and the conductive material pattern 75. A lower insulating film 40 may be disposed around the first plug 84 and the second plug 88.

The lower insulating film 40 may surround or cover lower sidewalls of the first plug 84 and the second plug 88. The lower insulating film 40 may have a bending shape at an upper surface thereof. The lower insulating film 40 may have unevenness at the upper surface thereof, e.g., the upper surface of the lower insulating film 40 may not be flat. For example, the lower insulating film 40 may have a convex portion CVP, a first concave portion CCP1, and a second concave portion CCP2.

The convex portion CVP of the lower insulating film 40 may be adjacent to sidewalls of the first plug 84 and the second plug 88. The lower insulating film 40 may have a first upper surface TS1 at the convex portion CVP thereof. The first upper surface TS1 may be disposed on an uppermost level in an upper portion of the lower insulating film 40. The first upper surface TS1 may be lower than upper surfaces of the first plug 84 and the second plug 88.

The first concave portion CCP1 and the second concave portion CCP2 may be disposed farther from the sidewalls of the first plug 84 and the second plug 88 than the convex portion CVP. The lower insulating film 40 may have a second upper surface TS2 at the first concave portion CCP1. The second upper surface TS2 may be lower than the first upper surface TS1.

The lower insulating film 40 may have a third upper surface TS3 at the second concave portion CCP2. The third upper surface TS3 may be lower than the second upper surface TS2. The lower insulating film 40 may include an insulating material. For example, the lower insulating film 40 may include silicon oxide. The lower insulating film 40 may have an etching rate different from an etching rate of the first landing pattern 34 and the second landing pattern 38.

The lower insulating film 40 may have an etching rate different from an etching rate of the material film 20. The lower insulating film 40 may help prevent an electrical short from occurring between the first landing pattern 34 and the second landing pattern 38 and between the first plug 84 and the second plug 88. The lower insulating film 40 may help prevent an electrical short from occurring between the first landing pattern 34 and the second plug 88 and between the second landing pattern 38 and the first plug 84.

The first spacer 94 and the second spacer 98 may be disposed on the lower insulating film 40. The first spacer 94 and the second spacer 98 may surround or cover upper sidewalls of the first plug 84 and the second plug 88, respectively. The first spacer 94 and the second spacer 98 may be disposed on the convex portion CVP of the lower insulating film 40. An upper portion of the first spacer 94 may protrude or extend higher than the upper surface of the first plug 84.

An upper portion of the second spacer 98 may protrude or extend higher than the upper surface of the second plug 88. The first spacer 94 and the second spacer 98, together with the lower insulating film 40, may electrically insulate the first plug 84 and the second plug 88 from neighboring elements. A lower surface of the first spacer 94 may have a predetermined width W2.

As shown in FIG. 1C, when the first spacer 94 is viewed along line II-II′ of FIG. 1A, the first spacer 94 may be disposed on the convex portion CVP of the lower insulating film 40, and may be disposed to vertically align a sidewall of the first spacer 94 with an edge or end of the third upper surface TS3 of the lower insulating film 40. The first interconnection line 153 may be disposed on the lower insulating film 40, the first plug 84, and the first spacer 94.

The first interconnection line 153 may be in contact with a central region of the upper surface of the first plug 84. The first interconnection line 153 may traverse side portions facing each other of the first spacer 94 on the first plug 84. The first interconnection line 153 may have a first lower surface on the first plug 84, and a second lower surface around the first spacer 94. The first lower surface of the first interconnection line 153 may be lower than an uppermost surface of the first plug 84.

A plane of the first lower surface of the first interconnection line 153 may be disposed between a plane of the first surface TS1 of the convex portion in the lower insulating film 40 and a plane of the uppermost surface of the first plug 84. For example, the plane of the first lower surface of the first interconnection line 153 may be disposed between the plane of the uppermost surface of the first plug 84 and a plane of the lower surface of the first spacer 94. The first lower surface of the first interconnection line 153 may be higher than the second upper surface TS2 of the lower insulating film 40.

As shown in FIG. 1C, the second lower surface of the first interconnection line 153 may be disposed on the third surface TS3 of the second concave portion CCP2 of the lower insulating film 40. The second lower surface of the first interconnection line 153 may be lower than the first lower surface of the first interconnection line 153. The second interconnection line 156 may be disposed between the first spacer 94 and the second spacer 98. The second interconnection line 156 may contact the first spacer 94 and the second spacer 98.

The second interconnection line 156 may extend from or past the first upper surface TS1 (of the convex portion in the lower insulating film 40) to the third surface TS3 (of the second concave portion CCP2). A lower surface of the second interconnection line 156 may be disposed on the third surface TS3 of the second concave portion CCP2. The second interconnection line 156 may be electrically insulated from the first plug 84 and the second plug 88 by the first spacer 94 and the second spacer 98, respectively.

The third interconnection line 159 may be in contact with a central region of the upper surface of the second plug 88. The third interconnection line 159 may traverse side portions facing each other of the second spacer 98 on the second plug 88. A lower surface of the third interconnection line 159 may be lower than an uppermost surface of the second plug 88.

A positional relationship of the uppermost surface of the first plug 84, the lower surface of the first spacer 94, and the lower surface of the first interconnection line 153 may be applied similarly to the uppermost surface of the second plug 88, the lower surface of the second spacer 98, and the lower surface of the third interconnection line 159. For example, the third interconnection line 159 may have the same shape as the first interconnection line 153.

The lower surfaces of the first interconnection line 153 and the third interconnection line 159 may be higher than the lower surface of the second interconnection line 156. Describing the first interconnection line 153 in more detail by referring to FIG. 1C, the first interconnection line 153 may contact the lower insulating film 40, the first plug 84 and the first spacer 94, and may have a first boundary surface, a second boundary surface, and a third boundary surface in the lower surface thereof.

The first boundary surface may be disposed at a first level. The first boundary surface may be at an interface of the upper surface of the first spacer 94 and the lower surface of the first interconnection line 153. The second boundary surface may be disposed at a second level. The second level may be lower than the first level. The second boundary surface may be at an interface of the upper surface of the first plug 84 and the lower surface of the first interconnection line 153.

The third boundary surface may be disposed at a third level. The third level may be lower than the second level. The third boundary surface may be at an interface of the third upper surface TS3 of the lower insulating film 40 and the lower surface of the first interconnection line 153. In an implementation, a fourth boundary surface may be at an interface of the first upper surface TS1 of the lower insulating film 40 and the lower surface of the first spacer 94.

The fourth boundary surface may be lower than the second boundary surface, and may be higher than the third boundary surface. The third interconnection line 159 may also have first to third boundary surfaces with respect to the lower insulating film 40, the second plug 88, and the second spacer 98, similarly to the first interconnection line 153.

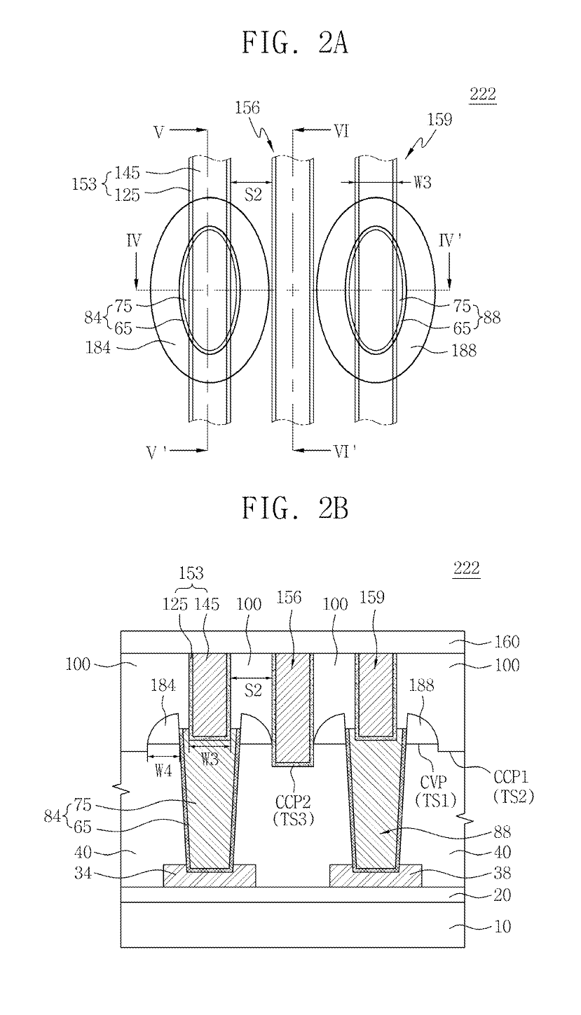

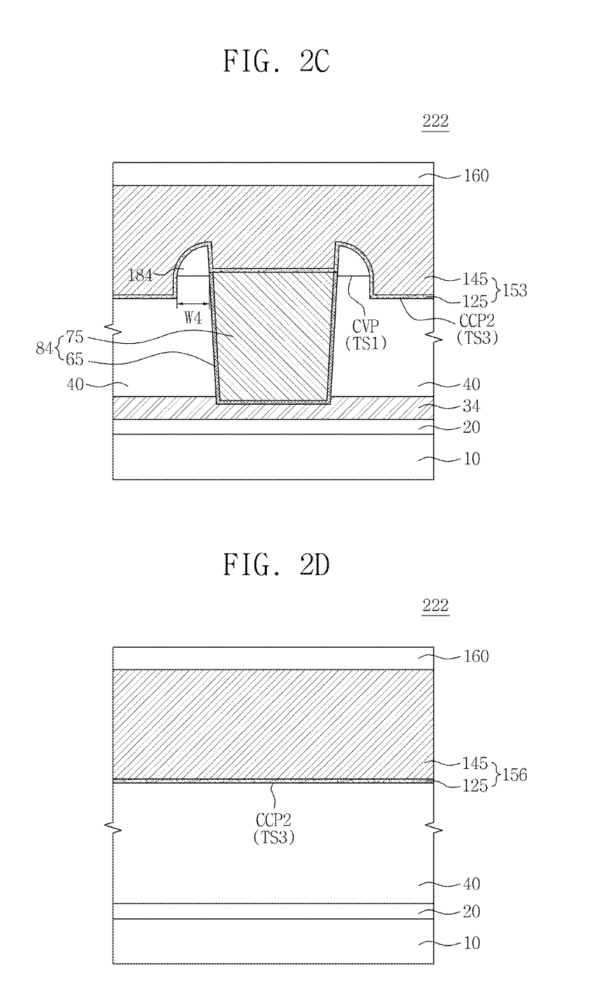

FIG. 2A illustrates a top view or a plan view of a semiconductor device according to an embodiment. FIGS. 2B to 2D illustrate longitudinal sectional views of the semiconductor device taken along lines IV-IV′, V-V′, and VI-VI′ of FIG. 2A.

Referring to FIG. 2A, a semiconductor device 222 according to the present embodiment may have an arrangement structure similar to elements of the semiconductor device 221 of FIG. 1A. For example, first to third interconnection lines 153, 156, and 159 of the semiconductor device 222 may be spaced apart from each other by a predetermined distance S2. The distance S2 between the first to third interconnection lines 153, 156, and 159 may be larger than the distance S1 between the first to third interconnection lines 153, 156, and 159 of FIG. 1A.

Each of the first to third interconnection lines 153, 156, and 159 may have a predetermined width W3. The width W3 may be larger than the width W1 of FIG. 1A. Each of a first spacer 184 and a second spacer 188 in the semiconductor device 222 may have a width larger than a width of each of the first spacer 94 and the second spacer 98 in the semiconductor device 221 of FIG. 1A.

Referring to FIGS. 2B to 2D, the semiconductor device 222 according to the present embodiment may have elements similar to the semiconductor device 221 of FIGS. 1A, 1C, and 1D, and a positional relationship of elements similar to the semiconductor device 221. A width W4 of a lower surface of the first spacer 184 in the semiconductor device 222 may be larger than the width W2 of the lower surface of the first spacer 94 in FIG. 1A.

The second spacer 188 may be disposed at a same level as the first spacer 184. A lower surface of the second spacer 188 may have a same width W4 as the lower surface of the first spacer 184. In FIG. 2B, the first interconnection line 153 may be disposed between side portions of the first spacer 184. The third interconnection line 159 may be disposed between side portions of the second spacer 188.

The second interconnection line 156 may be disposed between the first spacer 184 and the second spacer 188. The second interconnection line 156 may fill a predetermined region between the first spacer 184 and the second spacer 188. The first to third interconnection lines 153, 156, and 159 may be spaced apart from each other by the predetermined distance S2.

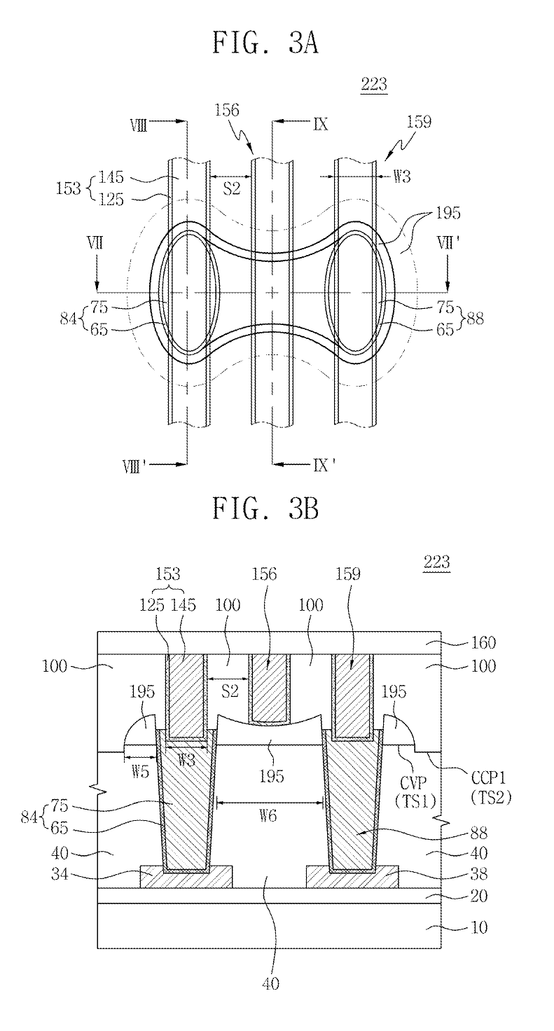

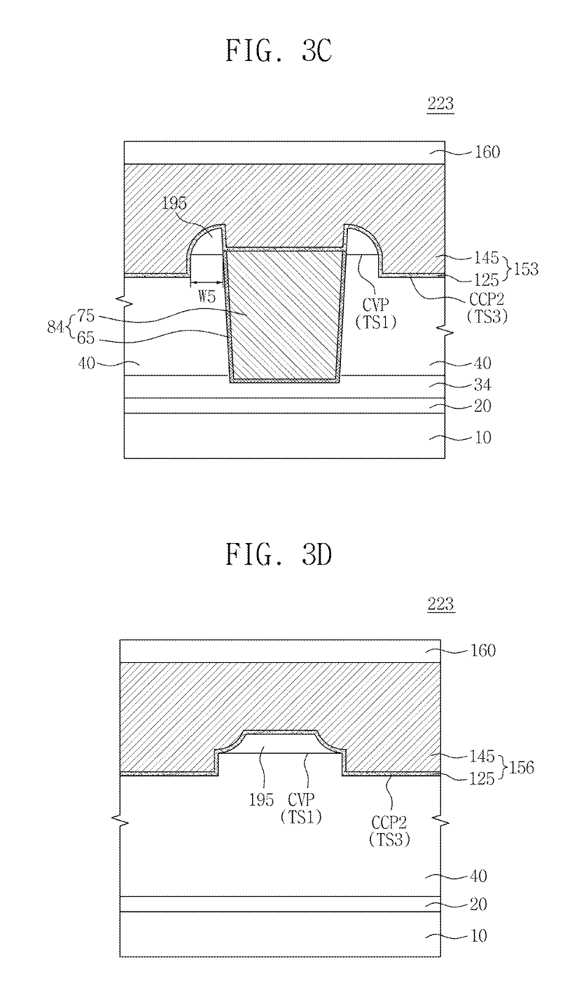

FIG. 3A illustrates a top view or a plan view of a semiconductor device according to an embodiment. FIGS. 3B to 3D illustrate longitudinal sectional views of the semiconductor device taken along lines VII-VII′, VIII-VIII′, and IX-IX′ of FIG. 3A.

Referring to FIGS. 3A to 3D, a semiconductor device 223 according to the present embodiment may have a positional relationship of elements similar to the semiconductor device 221 according to the previous embodiment. For example, a spacer 195 of the semiconductor device 223 may have a different shape from the first and second spacers 184 and 188 of FIG. 2A. The spacer 195 may be formed in one body, e.g., may be monolithically formed, and may surround a first plug 84 and a second plug 88 in the semiconductor device 223.

The spacer 195 may have a similar profile to the first and second spacers 184 and 188 of FIGS. 2B and 2C, at side portions of the first and second plugs 84 and 88, except for a central portion between the first and second plugs 84 and 88. A lower surface of the spacer 195 may have a predetermined width W5 at the side portions of the first and second plugs 84 and 88.

The width W5 of the spacer 195 may be the same size as or a different size from the width W4 of the lower surface of the first spacer 184 in FIG. 2C. The spacer 195 may have a predetermined width W6 between the first and second plugs 84 and 88. A first interconnection line 153 may be in contact with the spacer 195, as shown in FIG. 3C. The first interconnection line 153 may be disposed on a third surface TS3 of a second concave portion CCP2 of a lower insulating film 40.

The first interconnection line 153 may be in contact with the third surface TS3 of the second concave portion CCP2. The second interconnection line 156 may be disposed on the third surface TS3 of the second concave portion CCP2 as shown in FIGS. 3B and 3D. The second interconnection line 156 may be disposed on the spacer 195 between the first and second plugs 84 and 88.

The second interconnection line 156 may have a first lower surface on the third surface TS3 of the second concave portion CCP2 as shown FIG. 3D. The second interconnection line 156 may be disposed on the spacer 195 at a convex portion CVP of the lower insulating film 40. The second interconnection line 156 may have a second lower surface along a bending or curve of the spacer 195 at the convex portion CVP of the lower insulating film 40.

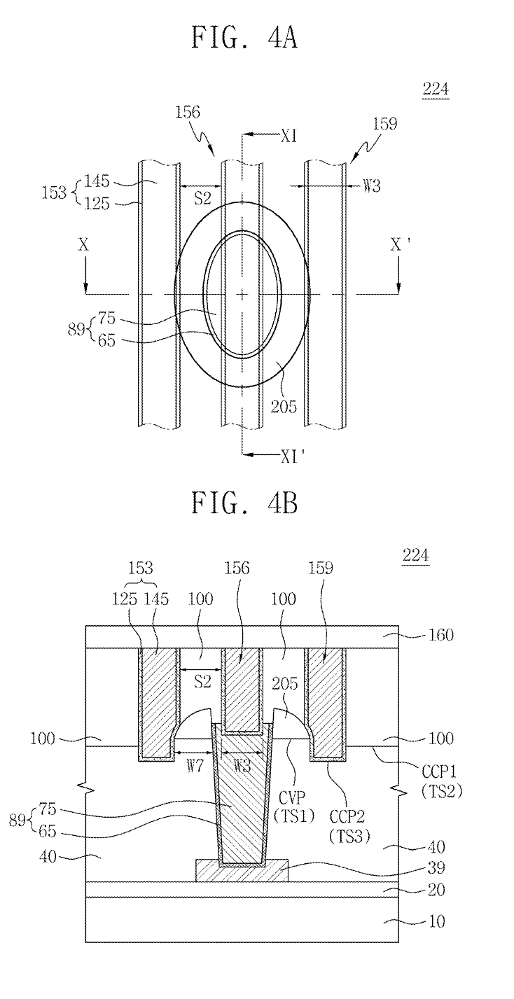

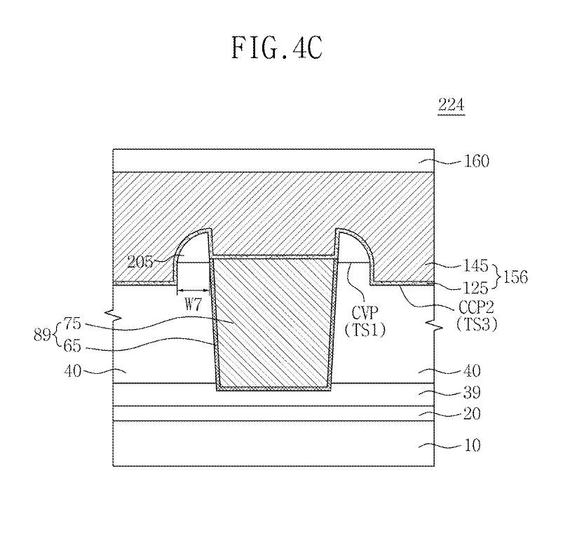

FIG. 4A illustrates a top view or a plan view of a semiconductor device according to an embodiment. FIGS. 4B and 4C illustrate longitudinal sectional views of the semiconductor device taken along lines X-X′, and XI-XI′ of FIG. 4A.

Referring to FIG. 4A, a semiconductor device 224 according to the present embodiment may have a positional relationship of elements similar to the semiconductor device 222 of FIG. 2A. For example, a second interconnection line 156 of first to third interconnection lines 153, 156, and 159 in the semiconductor device 224 may intersect a plug 89. A spacer 205 may be disposed around the plug 89. The spacer 205 may surround an upper sidewall of the plug 89.

Referring to FIGS. 4B and 4C, the semiconductor device 224 according to the present embodiment may have elements similar to the semiconductor device 222 of FIGS. 2B, 2C, and 2D, and a positional relationship similar to elements of the semiconductor device 222. A lower surface of the spacer 205 may have a predetermined width W7, which may be the same as or different from the width W4 of the lower surface of the first spacer 94 or the second spacer 98 in FIG. 2B.

First to third interconnection lines 153, 156, and 159 may be disposed on a lower insulating film 40, the plug 89, and the spacer 205. The first and third interconnection lines 153 and 156 may be disposed around the spacer 205 and may overlap with the spacer 205. The second interconnection line 156 may be disposed between side portions of the spacer 205.

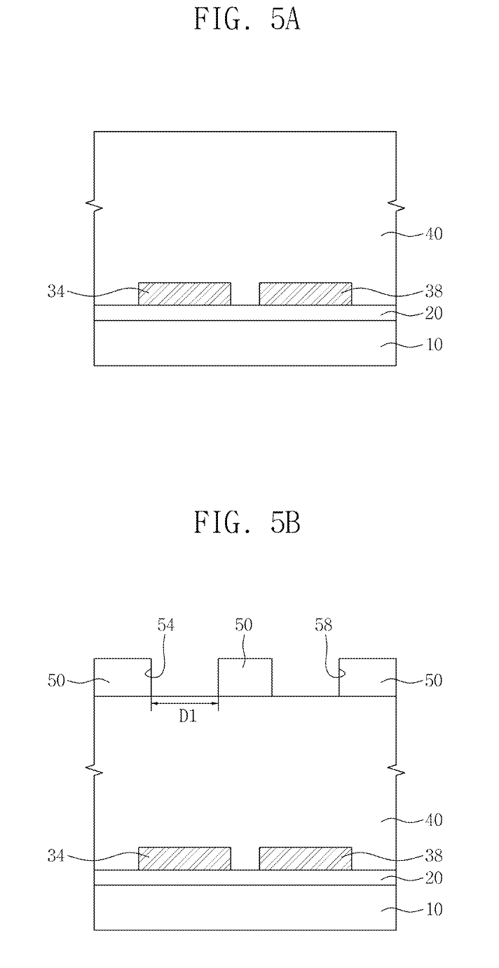

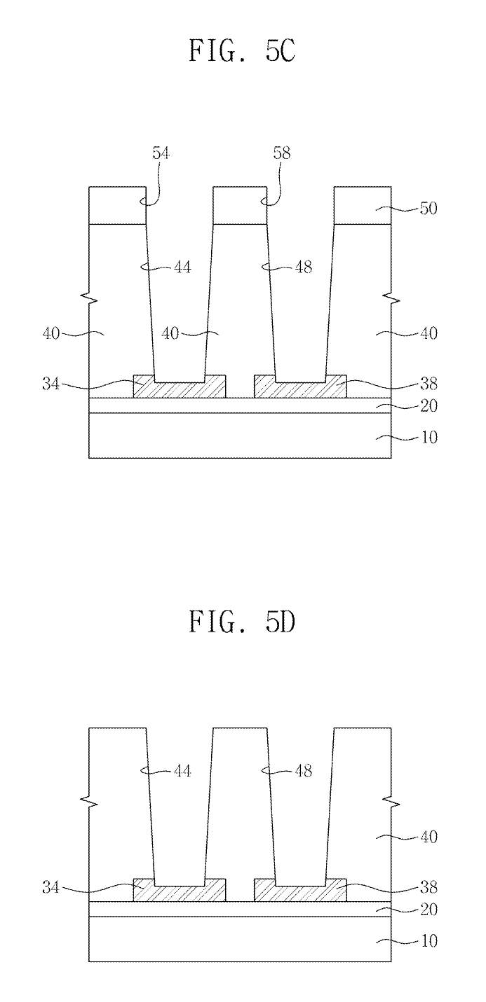

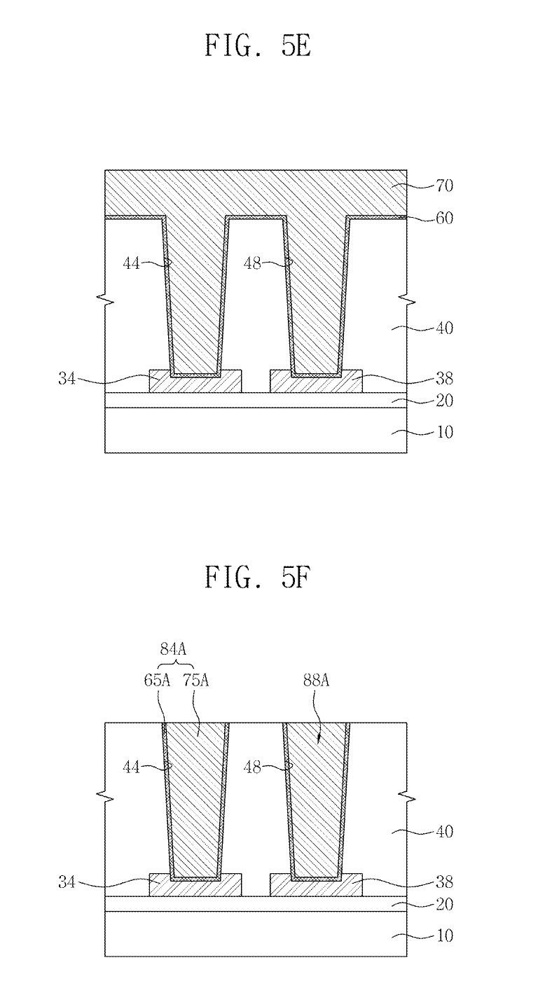

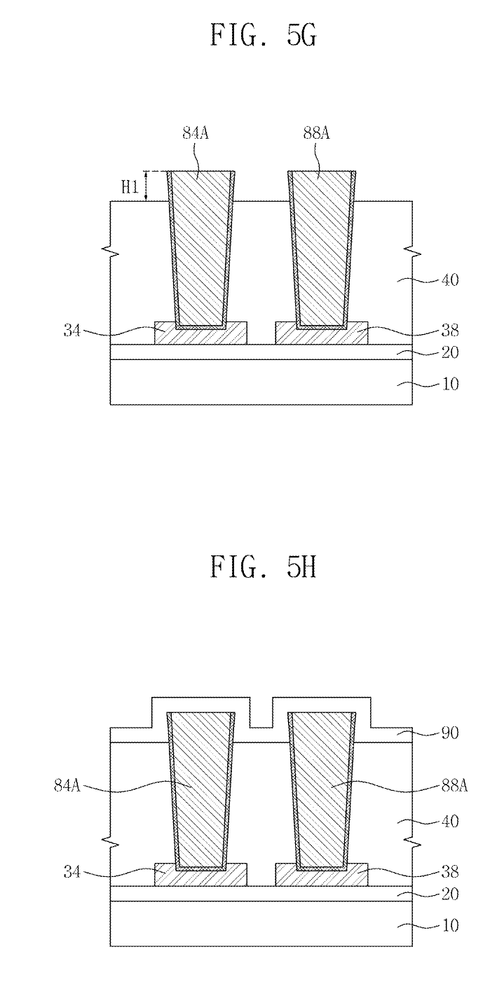

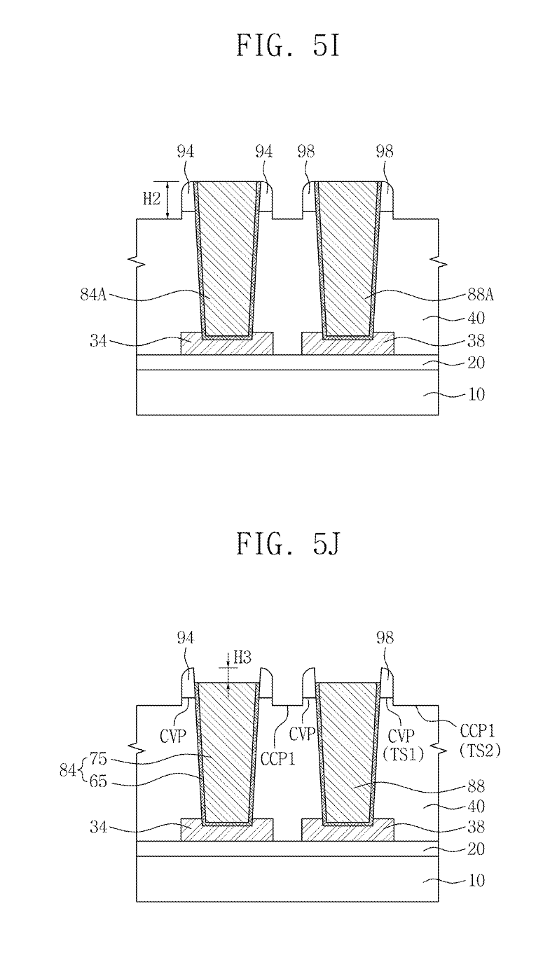

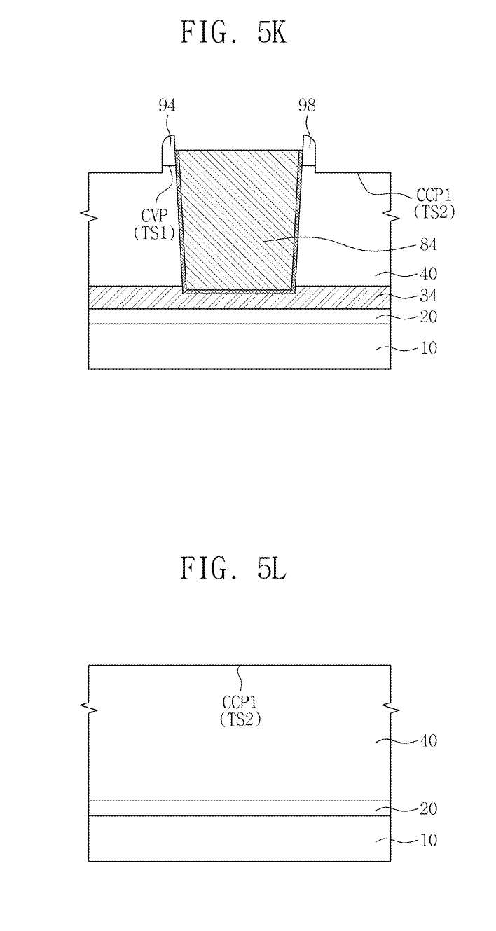

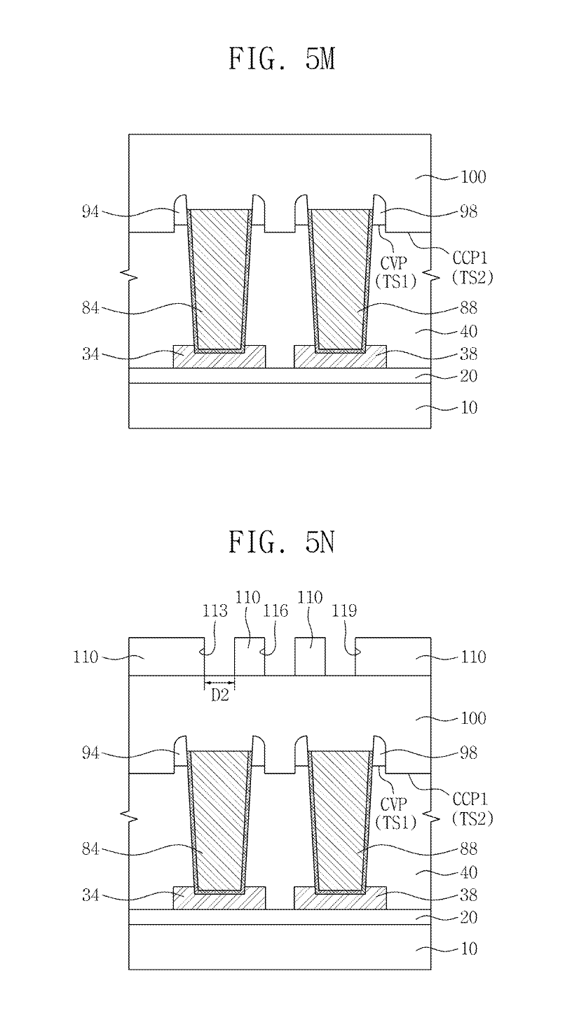

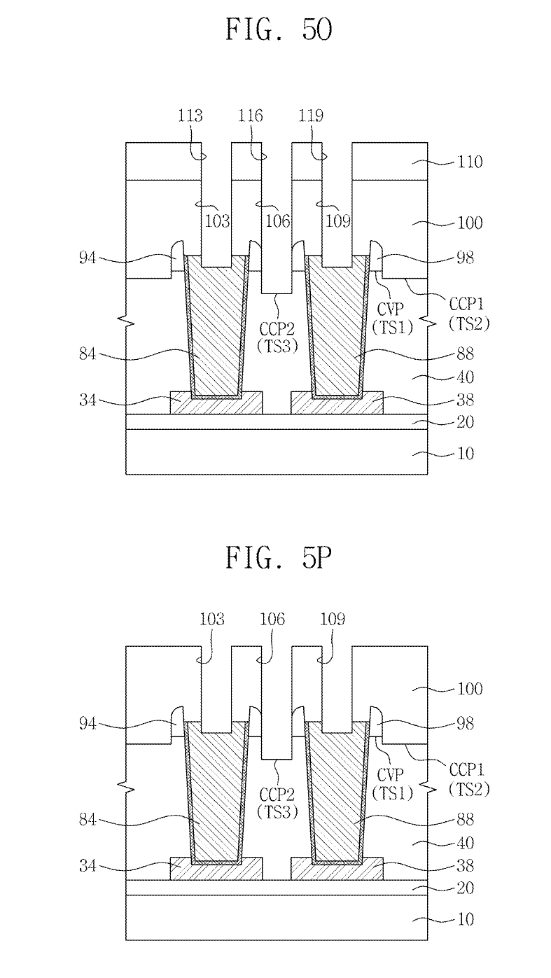

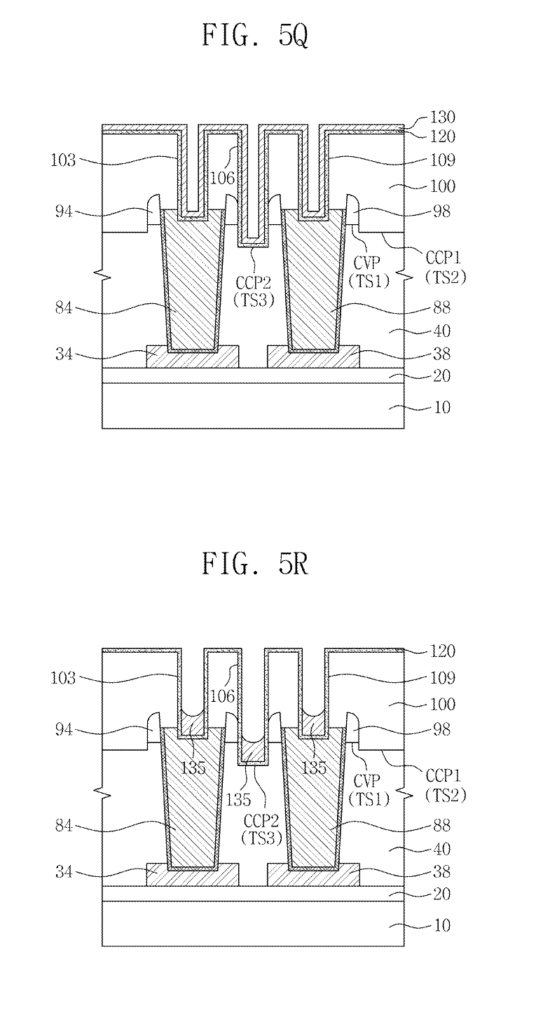

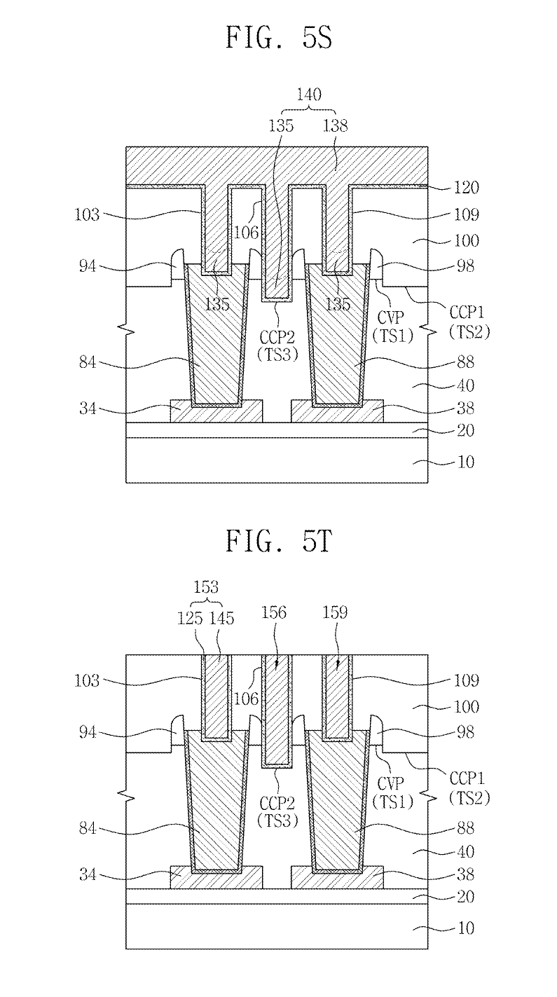

Next, a method of forming a semiconductor device according to an embodiment will be described by referring to FIGS. 5A to 5T.

FIGS. 5A to 5I illustrate longitudinal sectional views showing stages in a method of forming a semiconductor device taken along line I-I′ of FIG. 1A according to an embodiment.

Referring to FIG. 5A, a semiconductor substrate 10 may be prepared. The semiconductor substrate 10 may include transistors and/or data storage patterns thereon. The semiconductor substrate 10 may include, e.g., a single crystalline silicon substrate or a silicon-on-insulator (SOI) substrate. A material film 20 may be formed on the semiconductor substrate 10.

The material film 20 may electrically insulate the transistors and the data storage patterns from each other, or may insulate the transistors and the data storage patterns from neighboring elements thereof. The material film 20 may include an insulating material, e.g., silicon oxide. First and second landing patterns 34 and 38 may be formed on the material film 20.

The first and second landing patterns 34 and 38 may have, e.g., a pad shape or a line shape. The first and second landing patterns 34 and 38 may be electrically connected to the transistors and/or the data storage patterns. The first and second landing patterns 34 and 38 may lead to an effective arrangement of elements for preventing direct contact between the semiconductor substrate 10 and elements formed subsequently on the semiconductor substrate 10. The first and second landing patterns 34 and 38 may include a conductive material.

A lower insulating film 40 may be formed on the first and second landing patterns 34 and 38. The lower insulating film 40 may cover the material film 20. The lower insulating film 40 may be disposed between the first and second landing patterns 34 and 38 to electrically insulate the first and second landing patterns 34 and 38. The lower insulating film 40 may include an insulating material, e.g., silicon oxide. The lower insulating film 40 may have an etching rate different from an etching rate of the first and second landing patterns 34 and 38.

The lower insulating film 40 may have an etching rate different from an etching rate of the material film 20. The lower insulating film 40 may be formed using, e.g., a chemical vapor deposition technique, a physical deposition technique, or a spin coating technique.

Referring to FIG. 5B, a photoresist film 50 may be formed on the lower insulating film 40. The photoresist film 50 may have first and second openings 54 and 58. The first and second openings 54 and 58 may have a circular shape or an elliptical shape when being viewed in a top view or a plan view. In an implementation, the first and second openings 54 and 58 may be formed in an elliptical shape when being viewed in a top view or a plan view.

The first and second openings 54 and 58 may be aligned with the first and second landing patterns 34 and 38, respectively. The photoresist film 50 may be used as an etching mask in a subsequent etching process. The first and second openings 54 and 58 may have a predetermined diameter (or width) D1.

Referring to FIG. 5C, portions of the lower insulating film 40 may be selectively removed by using the photoresist film 50 as an etching mask. By removing portions of the lower insulating film 40, a first contact hole 44 and a second contact hole 48 may be formed in the lower insulating film 40. The first contact hole 44 and the second contact hole 48 may have a hollow pillar shape. The first contact hole 44 and the second contact hole 48 may expose the first and second landing patterns 34 and 38, respectively.

Referring to FIG. 5D, the photoresist film 50 may be removed. In an implementation, sidewalls of the first contact hole 44 and the second contact hole 48 may be tapered. In another implementation, the sidewalls of the first contact hole 44 and the second contact hole 48 may be perpendicular to upper surfaces of the first and second landing patterns 34 and 38.

In an implementation, lower surfaces of the first contact hole 44 and the second contact hole 48 may be lower than uppermost surfaces of the first and second landing patterns 34 and 38. In another implementation, lower surfaces of the first contact hole 44 and the second contact hole 48 may be at the same level as the uppermost surfaces of the first and second landing patterns 34 and 38.

Referring to FIG. 5E, a diffusion barrier film 60 and a conductive material film 70 may be sequentially formed on the first landing patterns 34, the second landing pattern 38, and the lower insulating film 40. The diffusion barrier film 60 may be conformally formed on the first landing patterns 34, the second landing pattern 38, and the lower insulating film 40 along the first contact hole 44 and the second contact hole 48.

The diffusion barrier film 60 may include at least one of tantalum, tantalum nitride, titanium, titanium nitride, and tungsten nitride. The diffusion barrier film 60 may help prevent elements of the conductive material film 70 from diffusing into the first landing patterns 34, the second landing pattern 38, and the lower insulating film 40. The diffusion barrier film 60 may be formed using a chemical vapor deposition technique or a physical deposition technique.

The conductive material film 70 may be formed on the diffusion barrier film 60 to fill the first contact hole 44 and the second contact hole 48. The conductive material film 70 may include, e.g., tungsten. The conductive material film 70 may be formed using a chemical vapor deposition technique or a physical deposition technique.

Referring to FIG. 5F, portions of the diffusion barrier film 60 and the conductive material film 70 may be removed and planarized to expose the lower insulating film 40. The diffusion barrier film 60 and the conductive material film 70 may be planarized using a chemical mechanical polishing technique. Remaining portions of the diffusion barrier film 60 and the conductive material film 70 may be transformed into a first preliminary plug 84A (in the first contact hole 44) and a second preliminary plug 88A (in the second contact hole 48).

For example, each of the first preliminary plug 84A and the second preliminary plug 88A may include a preliminary diffusion barrier pattern 65A and a preliminary conductive material pattern 75A. The preliminary conductive material pattern 75A may provide the first preliminary plug 84A and the second preliminary plug 88A with conductivity. Resistance of the first preliminary plug 84A and the second preliminary plug 88A may be controlled by the preliminary diffusion barrier pattern 65A and the preliminary conductive material pattern 75A.

Referring to FIG. 5G, the lower insulating film 40 may be partially removed using the first preliminary plug 84A and the second preliminary plug 88A as an etching buffer film. The lower insulating film 40 may be removed using a dry or wet etching technique. By removing portions of the lower insulating film 40, upper surfaces of the first preliminary plug 84A and the second preliminary plug 88A may protrude or extend by a predetermined height H1 from the lower insulating film 40. Upper sidewalls of the first preliminary plug 84A and the second preliminary plug 88A may be exposed from or above the lower insulating film 40.

Referring to FIG. 5H, a spacer film 90 may be formed on the first preliminary plug 84A and the second preliminary plug 88A. The spacer film 90 may be formed on the lower insulating film 40 to surround the upper surfaces and the upper sidewalls of the first preliminary plug 84A and the second preliminary plug 88A. The spacer film 90 may be conformally formed on the upper surfaces and the upper sidewalls of the first preliminary plug 84A and the second preliminary plug 88A.

For example, the spacer film 90 may not completely fill a predetermined region between the first preliminary plug 84A and the second preliminary plug 88A. The spacer film 90 may electrically insulate the upper sidewalls of the first preliminary plug 84A and the second preliminary plug 88A. The spacer film 90 may include an insulating material, e.g., silicon nitride and/or silicon oxynitride. The spacer film 90 may be formed using a chemical vapor deposition technique or a physical deposition technique.

Referring to FIG. 5I, portions of the spacer film 90 may be removed to expose the lower insulating film 40, the first preliminary plug 84A, and the second preliminary plug 88A. The spacer film 90 may be removed using a dry etching technique. By removing the portions of the spacer film 90, remaining portions of the spacer film 90 may be transformed into a first spacer 94 and a second spacer 98 on the upper sidewalls of the first preliminary plug 84A and the second preliminary plug 88A.

The first spacer 94 and the second spacer 98 may be symmetrically formed around the first preliminary plug 84A and the second preliminary plug 88A. Each of lower surfaces of the first spacer 94 and the second spacer 98 may have the width W2 (as shown in FIG. 1B). The first spacer 94 and the second spacer 98 may surround the upper sidewalls of the first preliminary plug 84A and the second preliminary plug 88A, respectively.

An upper surface of the lower insulating film 40 may have a step difference below the first spacer 94 and the second spacer 98, and around the first spacer 94 and the second spacer 98. The upper surfaces of the first preliminary plug 84A and the second preliminary plug 88A may be disposed at the same height H1 (as in FIG. 5G or 5H) from the upper surface of the lower insulating film 40, below the first spacer 94 and the second spacer 98.

The upper surfaces of the first preliminary plug 84A and the second preliminary plug 88A may protrude or extend by a predetermined height H2 from the upper surface of the lower insulating film 40, around the first spacer 94 and the second spacer 98. The height H2 may be greater than the height H1.

FIGS. 5J to 5L illustrate longitudinal sectional views showing stages in a method of forming a semiconductor device taken along lines I-I′, II-II′, and III-III′ of FIG. 1A.

Referring to FIG. 5J, portions of the first preliminary plug 84A and the second preliminary plug 88A of FIG. 5I may be partially removed using the lower insulating film 40, the first spacer 94, and the second spacer 98 as an etching buffer film. The portions of the first preliminary plug 84A and the second preliminary plug 88A may be removed using a dry or wet etching technique.

By removing the portions of the first preliminary plug 84A and the second preliminary plug 88A, upper surfaces of the first preliminary plug 84A and the second preliminary plug 88A may be recessed from an upper portion of the first spacer 94 and the second spacer 98, and remaining portions may be transformed into the first plug 84 and the second plug 88. For example, the first plug 84 and the second plug 88 may have stud shapes or pillar shapes, which may vertically extend from the first landing patterns 34 and the second landing pattern 38.

The first spacer 94 and the second spacer 98 may protrude a predetermined height H3 from upper surfaces of the first plug 84 and the second plug 88, respectively. Inner sidewalls of the first spacer 94 and/or the second spacer 98 may have a lower portion (in contact with upper sidewalls of the first plug 84 and/or the second plug 88) and upper portions (not in contact with, e.g., above, the upper sidewall of the first plug 84 or the second plug 88).

The first spacer 94 and the second spacer 98 may sufficiently electrically insulate the first plug 84 and the second plug 88 from elements formed through subsequent processes. For example, the lower insulating film 40 may have a convex portion CVP and first concave portions CCP1 at an upper portion thereof. The convex portion CVP of the lower insulating film 40 may be disposed below the first spacer 94 and the second spacer 98.

The first concave portions CCP1 of the lower insulating film 40 may be disposed around the first spacer 94 and the second spacer 98. The lower insulating film 40 may have a first upper surface TS1 at the convex portion CVP. The first upper surface TS1 may be disposed at an uppermost level in the upper portion of the lower insulating film 40. The lower insulating film 40 may have second upper surfaces TS2 at the first concave portions CCP1, respectively. The second upper surfaces TS2 may be lower than the first upper surface TS1.

Referring to FIG. 5K, when the first plug 84 and the first spacer 94 are viewed along line II-II′ of FIG. 1A, the upper sidewall of the first plug 84 may be in contact with the first spacer 94. The first spacer 94 may have a similar shape to that shown in FIG. 5J, with respect to the upper sidewall of the first plug 84. The lower insulating film 40 may have a similar shape to that shown in FIG. 5J, below and around the first spacer 94.

Referring to FIG. 5L, when the lower insulating film 40 is viewed along line III-III′ of FIG. 1A, the lower insulating film 40 may have the first concave portion CCP1 between the first spacer 94 and the second spacer 98 in FIG. 5J. The first concave portion CCP1 of the lower insulating film 40 may be covered with or form the second upper surface TS2.

FIGS. 5M to 5T illustrate longitudinal sectional views showing stages in a method of forming a semiconductor device taken along line I-I′ of FIG. 1A according to an embodiment.

Referring to FIG. 5M, an upper insulating film 100 may be formed on the lower insulating film 40. The upper insulating film 100 may cover the first plug 84, the second plug 88, the first spacer 94, and the second spacer 98. The upper insulating film 100 may fill the first concave portions CCP1 of the lower insulating film 40.

The upper insulating film 100 may sufficiently electrically insulate the first plug 84 and the second plug 88 from elements formed in subsequent processes, together with the first spacer 94 and the second spacer 98. The upper insulating film 100 may include an insulating material, e.g., silicon oxide. The upper insulating film 100 may have the same etching rate as or a different etching rate from that of the lower insulating film 40. The upper insulating film 100 may be formed using a chemical vapor deposition technique, a physical deposition technique, or a spin coating technique.

Referring to FIG. 5N, a second photoresist film 110 may be formed on the upper insulating film 100. The second photoresist film 110 may have a first opening 113, a second opening 116, and a third opening 119. The first to third openings 113, 116, and 119 may have a trench or groove shape. The first and third openings 113 and 119 may be aligned with the first plug 84 and the second plug 88, respectively.

The second opening 116 may be aligned between the first spacer 94 and the second spacer 98. The first to third openings 113, 116, and 119 may be formed to correspond to the first to third interconnection lines 153, 156, and 159 (see FIG. 1A), respectively. Each of the first to third openings 113, 116, and 119 may have a predetermined width (or diameter) D2.

Referring to FIG. 50, portions of the upper insulating film 100 may be removed by using the second photoresist film 110 as an etching mask. The upper insulating film 100 may be removed using a dry etching technique. By removing the portions of the upper insulating film 100, a first trench 103, a second trench 106, and a third trench 109 may be formed in the upper insulating film 100.

The first to third trenches 103, 106, and 109 may have the same width as or a different width as the first to third openings 113, 116, and 119. The first to third trenches 103, 106, and 109 may be spaced apart from each other by the distance S1 (see FIG. 1B).

The first and third trenches 103 and 109 may expose portions of the first plug 84 and the second plug 88, respectively. The second trench 106 may expose portions of the lower insulating film 40 between the first spacer 94 and the second spacer 98.

Referring to FIG. 5P, the second photoresist film 110 may be removed from the upper insulating film 100. The first and third trenches 103 and 109 may respectively extend from uppermost surfaces of the first plug 84 and the second plug 88 into interiors thereof. For example, the first and third trenches 103 and 109 may have lower surfaces below uppermost surfaces of the first plug 84 and the second plug 88, respectively.

A plane of the lower surface of the first trench 103 may be disposed between a plane of the uppermost surface of the first plug 84 and a plane of the lower surface of the first spacer 94. The lower surface of the third trench 109 may be disposed between the upper surface of the second plug 88 and the lower surface of the second spacer 98.

When viewed along line II-II′ of FIG. 1A, the lower surface of each of the first and third trenches 103 and 109 (around the first plug 84 and the second plug 88) may be a third upper surface TS3 of a second concave portion CCP2 of the lower insulating film 40.

The second trench 106 may expose sidewalls of the first and second spacers 94 and 98. The second trench 106 may pass through a region between the first and second spacers 94 and 98 to extend into the lower insulating film 40. The second trench 106 may be self-aligned between the first and second spacers 94 and 98 to form the second concave portion CCP2 in the lower insulating film 40.

The lower insulating film 40 may have the third upper surface TS3 at the second concave portion CCP2. The third upper surface TS3 may be lower than the second upper surface TS2. A height of a sidewall of the second trench 106 may be greater than heights of sidewalls of the first trench 103 and the third trench 109.

Referring to FIG. 5Q, a barrier film 120 and a seed film 130 may be sequentially formed on the lower insulating film 40, the first plug 84, the second plug 88, and the upper insulating film 100. The barrier film 120 and the seed film 130 may be conformally formed on the first to third trenches 103, 106, and 109. In an implementation, the barrier film 120 may include the same material as the diffusion barrier film 60.

The barrier film 120 may be formed using a chemical vapor deposition technique or a physical deposition technique. The seed film 130 may include, e.g., copper. The seed layer 130 may be used to form a filling film 138 (see FIG. 5S) sufficiently filled in the first to third trenches 103, 106, and 109. The seed film 130 may be formed using a chemical vapor deposition technique or a physical deposition technique.

The barrier film 120 may help prevent impurities (of the lower insulating film 40, the first plug 84, the second plug 88, the first spacer 94, the second spacer 98, and the upper insulating film 100) from diffusing into the seed film 130 and/or the filling film 138.

Referring to FIG. 5R, the seed film 130 may be heated. For example, the seed film 130 may melt and flow to an upper surface (e.g., of a bottom portion) of the barrier film 120, and may be transformed into seed patterns 135 in the first to third trenches 103, 106, and 109. The seed patterns 135 may partially fill the first to third trenches 103, 106, and 109.

Referring to FIG. 5S, the filling film 138 may be formed on the seed patterns 135. The filling film 138 may sufficiently fill the first to third trenched 103, 106, and 109. The filling film may include, e.g., copper. The filling film 138 may be formed by using, e.g., an electroplating technique. The filling film 138 may constitute a conductive film 140 together with the seed patterns 135.

Referring to FIG. 5T, portions of the barrier film 120 and the conductive film 140 may be removed to expose the upper insulating film 100. By removing the portions of the barrier film 120 and the conductive film 140, remaining portions of the barrier film 120 and the conductive film 140 may be transformed into first to third interconnection lines 153, 156, and 159 in the first to third trenches 103, 106, and 109.

The first to third interconnection lines 153, 156, and 159 may have a line shape that extends horizontally, when being viewed in a top view or a plan view of FIG. 1A. The first and third interconnection lines 153 and 159 may intersect and contact the first and second spacers 94 and 98. The first to third interconnection lines 153, 156, and 159 may be referred to as wires.

Each of the first to third interconnection lines 153, 156, and 159 may include a barrier pattern 125 and a conductive pattern 145. The conductive pattern 145 (together with the barrier pattern 125) may provide the first to third interconnection lines 153, 156, and 159 with conductivity. Each of the first to third interconnection lines 153, 156, and 159 may have the width W1 (see FIG. 1B).

Then, a protection film 160 (see FIG. 1B, 1C, or 1D) may be formed on the upper insulating film 100 and the first to third interconnection lines 153, 156, and 159. The protection film 160 may include an insulating material, e.g., silicon nitride or silicon oxynitride. The protection film 160 may be formed using a chemical vapor deposition technique or a physical deposition technique.

The protection film 160 may be included in the semiconductor device 221, together with the first and second plugs 84 and 88, the first and second spacers 94 and 98, and the first to third interconnection lines 153, 156, and 159. In the semiconductor device 221, the first and third interconnection lines 153 and 159 may have a smaller volume than the second interconnection line 156.

However, in an implementation, the first and third interconnection lines 153 and 159 may have a relatively larger volume using the second concave portion CCP2 of the lower insulating film 40, as compared with when the first and third interconnection lines 153 and 159 are disposed on the convex portion CVP of the lower insulating film 40. The first and third interconnection lines 153 and 159 may have a process margin, capable of lowering resistance thereof using the second concave portion CCP2 of the lower insulating film 40.

The second interconnection line 156 may have a smaller resistance than the first and third interconnection lines 153 and 159. The first to third interconnection lines 153, 156, and 159 may have good current transfer capability. The second interconnection line 156 may be electrically insulated from the first and third plugs 84 and 88 due to its location between the first and second spacers 94 and 98.

By providing the ring type first and second spacers 94 and 98 only around the first and second plugs 84 and 88, parasitic capacitance around the second interconnection line 156 may be relatively reduced. Thus, the parasitic capacitance around the second interconnection line 156 may be adjusted by properly transforming a geometric shape of the first and second spacers 94 and 98.

As a result, operation speed of the semiconductor device 221 may be increased by using the reduced resistance of each of the first to third interconnection lines 153, 156, and 159, and parasitic capacitance of the semiconductor device 221 may be reduced around the second interconnection line 156.

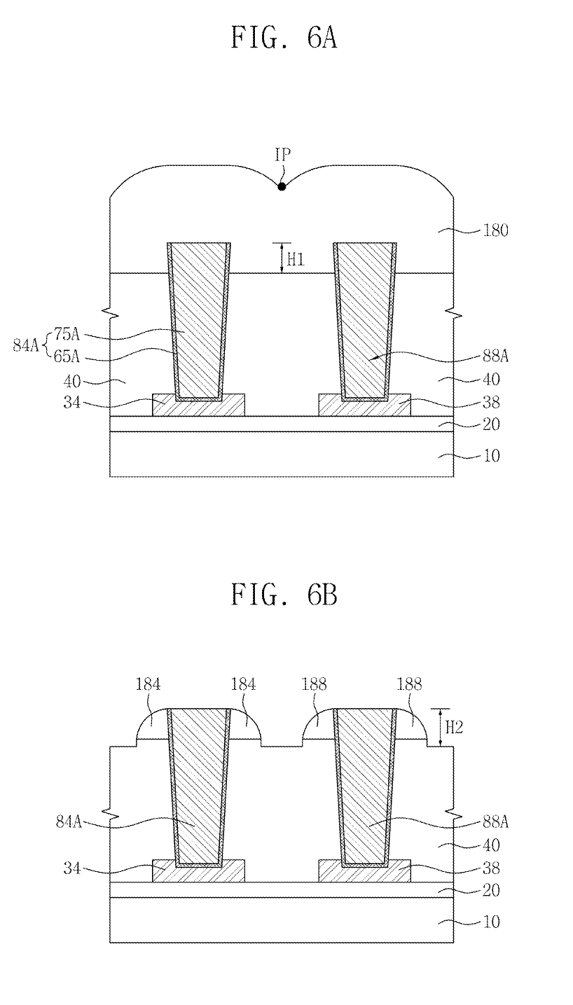

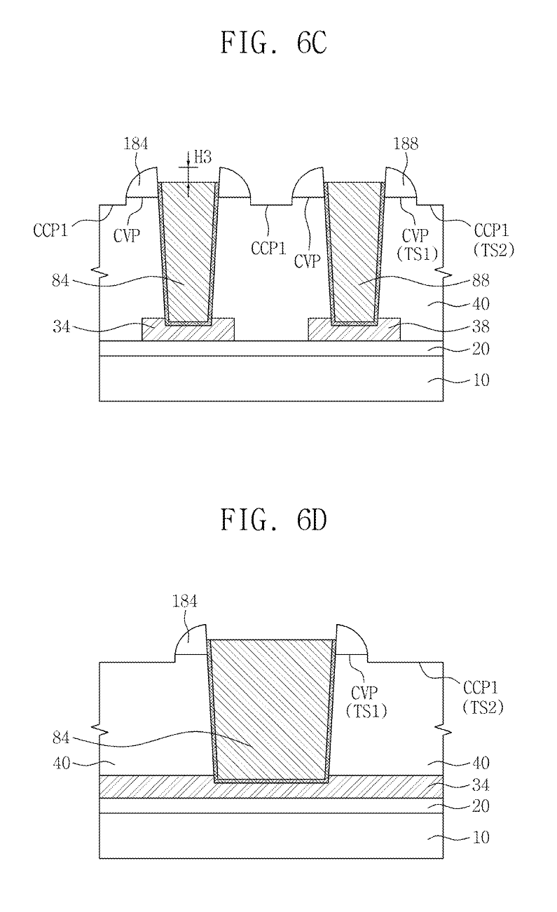

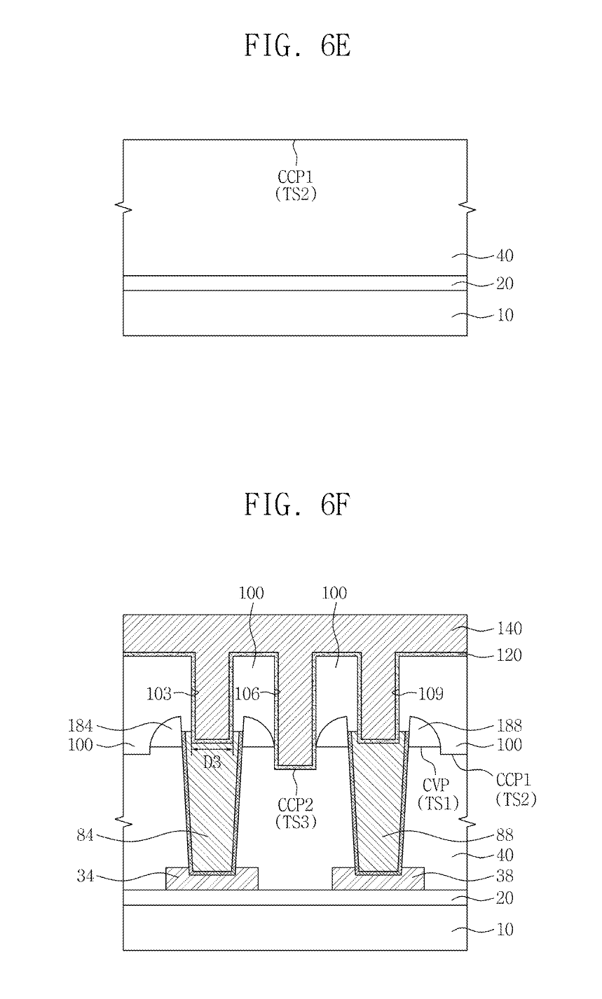

A method of forming a semiconductor device according to another embodiment will be described by referring to FIGS. 6A to 6F. In FIGS. 6A to 6F, the same reference numerals are used to denote the same components as in FIGS. 5A to 5T.

FIGS. 6A and 6B illustrate longitudinal sectional views showing stages in a method of forming a semiconductor device taken along line IV-IV′ of FIG. 2A according to an embodiment.

Referring to FIG. 6A, a spacer film 180 may be formed on a lower insulating film 40, a first preliminary plug 84A, and a second preliminary plug 88A (see FIG. 5G). The first preliminary plug 84A and the second preliminary plug 88A may protrude from the lower insulating film 40 by a predetermined height H1. The spacer film 180 may fill a region between the first preliminary plug 84A and the second preliminary plug 88A.

The spacer film 180 may be formed along the protruded shape of the first preliminary plug 84A and the second preliminary plug 88A from the lower insulating film 40. An upper surface of the spacer film 180 may have an inflection point IP or a bending or curved shape having a small curvature between the first preliminary plug 84A and the second preliminary plug 88A.

In an implementation, the upper surface of the spacer film 180 may have the same bending shape in side potions thereof and a central portion between the first preliminary plug 84A and the second preliminary plug 88A. In an implementation, the upper surface of the spacer film 180 may have different curvatures in the side potions thereof and the central portion between the first preliminary plug 84A and the second preliminary plug 88A. The spacer film 180 may include the same material as or a different material from the spacer film 90 (see FIG. 5H). The spacer film 180 may be formed using a chemical vapor deposition technique or a physical deposition technique.

Referring to FIG. 6B, portions of the spacer film 180 may be removed to expose the lower insulating film 40, the first preliminary plug 84A, and the second preliminary plug 88A. The spacer film 180 may be removed by a dry etching technique. By removing the portions of the spacer film 180, remaining portions of the spacer film 180 may be transformed into a first spacer 184 and a second spacer 188 on upper sidewalls of the first preliminary plug 84A and the second preliminary plug 88A.

The first spacer 184 and the second spacer 188 may be symmetrically formed around the first preliminary plug 84A and the second preliminary plug 88A, respectively. The first spacer 184 and the second spacer 188 may surround the first preliminary plug 84A and the second preliminary plug 88A, respectively. Lower surfaces of the first spacer 184 and the second spacer 188 may have the width W4 (see FIG. 2B).

For example, the lower insulating film 40 may be recessed around the first spacer 184 and the second spacer 188. An upper surface of the lower insulating film 40 may have a step difference below the first spacer 184 and the second spacer 188, and around the first spacer 184 and the second spacer 188.

Upper surfaces of the first preliminary plug 84A and the second preliminary plug 88A may extend or protrude by the height H1 (see FIG. 6A) from the upper surface of the lower insulating film 40, below the first spacer 184 and the second spacer 188. The upper surfaces of the first preliminary plug 84A and the second preliminary plug 88A may be disposed at a predetermined height H2 from the upper surface of the lower insulating film 40, around the first spacer 184 and the second spacer 188.

FIGS. 6C to 6E illustrate longitudinal sectional views showing stages in a method of forming a semiconductor device taken along lines IV-IV′, V-V′, and VI-VI′ of FIG. 2A according to an embodiment.

Referring to FIG. 6C, portions of the first preliminary plug 84A and the second preliminary plug 88A may be partially removed using the lower insulating film 40, the first spacer 184, and the second spacer 188 as an etching buffer film. By removing the portions of the first preliminary plug 84A and the second preliminary plug 88A, the first preliminary plug 84A and the second preliminary plug 88A may be recessed from upper portions of the first spacer 184 and the second spacer 188, and remaining portions of the first preliminary plug 84A and the second preliminary plug 88A may be transformed into a first plug 84 and a second plug 88.

The first spacer 184 and the second spacer 188 may protrude by a predetermined height H3 from upper surfaces of the first plug 84 and the second plug 88. The first plug 84, the second plug 88, the first spacer 184, and the second spacer 188 may have a positional relationship similar to the first plug 84, the second plug 88, first spacer 94, and the second spacer 98 of FIG. 5J.

For example, the lower insulating film 40 may have a convex portion CVP and first concave portions CCP1 at an upper portion thereof. The convex portion CVP, the first concave portions CCP1, the first spacer 184, and the second spacer 188 may have a positional relationship similar to the convex portion CVP, the first concave portions CCP1, the first spacer 94, and the second spacer 98 of the previous embodiment (see FIG. 5J).

The lower insulating film 40 may have a first upper surface TS1 at the convex portion CVP. The first upper surface TS1 may be disposed at an uppermost level in the upper portion of the lower insulating film 40. The lower insulating film 40 may have second upper surfaces TS2, respectively, at the first concave portions CCP1. The second upper surfaces TS2 may be lower than the first upper surface TS1.

Referring to FIG. 6D, when the first plug 84 and the first spacer 184 are viewed along line V-V′ of FIG. 2A, the first plug 84 and the first spacer 184 may have a positional relationship similar to the first plug 84 and the first spacer 94 (see FIG. 5K). The lower insulating film 40 may have a shape similar to the lower insulating film 40 of FIG. 5K, below and around the first spacer 184.

Referring to FIG. 6E, when the lower insulating film 40 is viewed along line VI-VI′ of FIG. 2A, the lower insulating film 40 may have the first concave portion CCP1 between the first spacer 184 and the second spacer 188.

FIG. 6F illustrates a longitudinal sectional view showing stages in a method of forming a semiconductor device taken along line IV-IV′ of FIG. 2A according to an embodiment.

Referring to FIG. 6F, process steps similar to those shown in FIGS. 5M to 5S may be used to form the lower insulating film 40. For example, in the present embodiment, the width D2 of each of the first to third openings 113, 116, and 119 in the second photoresist film 110 of FIG. 5N may be increased. Thus, each of first to third trenches 103, 106, and 109 according to the present embodiment may have a predetermined width D3.

A barrier film 120 and a conductive film 140 may be formed on an upper insulating film 100 to fill the first to third trenches 103, 106, and 109. Then, process steps similar to those shown in FIG. 5T may be used to form the barrier film 120 and the conductive film 140. The first to third trenches 103, 106, and 109 may be filled with the first interconnection line 153, the second interconnection line 156, and the third interconnection line 159 (see FIG. 5T), respectively.

The protection film 160 (see FIG. 2B) may be formed on the upper insulating film 100, the first interconnection line 153, the second interconnection line 156, and the third interconnection line 159. The protection film 160 may be included in the semiconductor device 222 according to the present embodiment, together with the first and second plugs 84 and 88, the first and second spacers 184 and 188, and the first to third interconnection lines 153, 156, and 159. The semiconductor device 222 may achieve the same effects as the semiconductor device 221 of FIG. 1A.

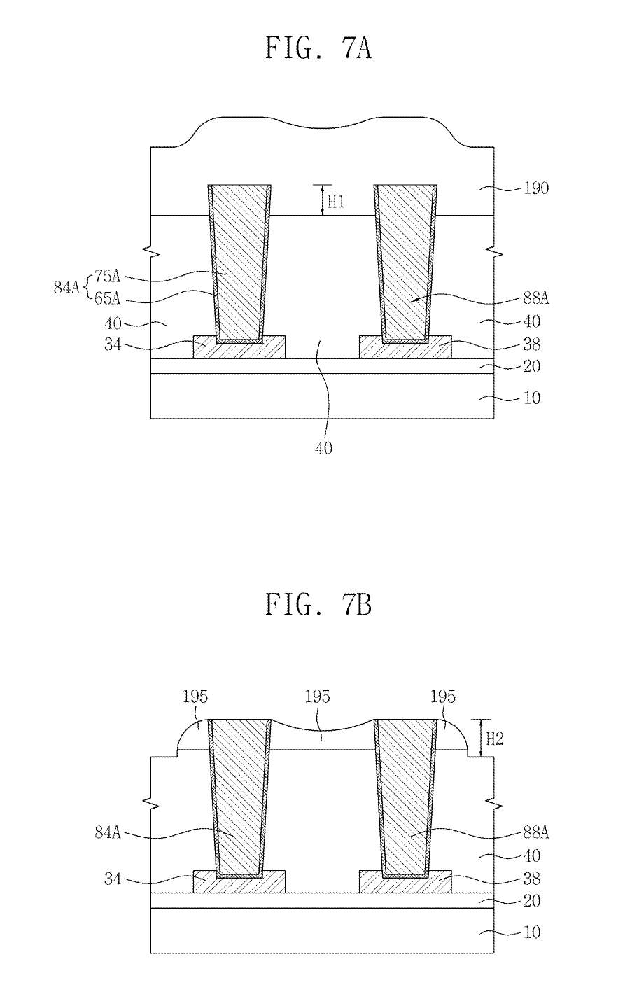

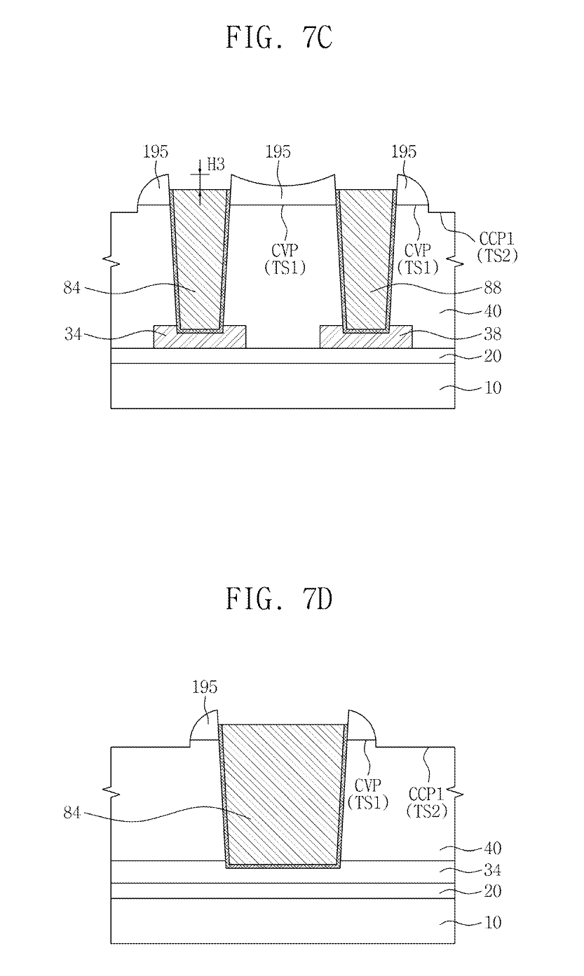

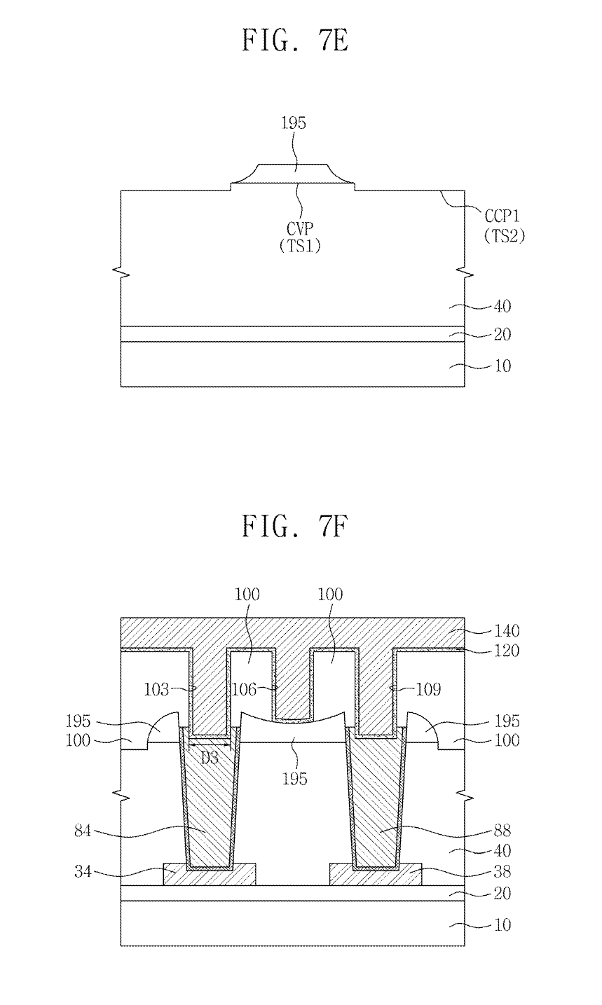

A method of forming a semiconductor device according to an embodiment will be described by referring to FIGS. 7A to 7F. In FIGS. 7A to 7F, the same reference numerals are used to denote the same components as those of the previous embodiments.

FIGS. 7A and 7B illustrate longitudinal sectional views showing stages in a method of forming a semiconductor device taken along line VII-VII′ of FIG. 3A according to an embodiment.

Referring to FIG. 7A, a spacer film 190 may be formed on a lower insulating film 40, a first preliminary plug 84A, and a second preliminary plug 88A (see FIG. 5G). The first preliminary plug 84A and the second preliminary plug 88A may protrude from the lower insulating film 40 by a predetermined height H1. The spacer film 190 may fill a region between the first preliminary plug 84A and the second preliminary plug 88A, differently from the spacer film 90 of FIG. 5H.

The spacer film 190 may be formed on the lower insulating film 40 along the protruded shape of the first preliminary plug 84A and the second preliminary plug 88A. An upper surface of the spacer film 190 may have a smaller bend in curvature than the upper surface of the spacer film 180 (see FIG. 6A), between the first preliminary plug 84A and the second preliminary plug 88A.

The upper surface of the spacer film 190 may have a larger bend in side portions of the first preliminary plug 84A and the second preliminary plug 88A than a central portion between the first preliminary plug 84A and the second preliminary plug 88A. The spacer film 190 may include the same material as or a different material from the spacer film 90. The spacer film 190 may be formed using a chemical vapor deposition technique or a physical deposition technique.

Referring to FIG. 7B, portions of the spacer film 190 may be removed to expose the lower insulating film 40, the first preliminary plug 84A, and the second preliminary plug 88A. The spacer film 190 may be removed using a dry etching technique. By removing the portions of the spacer film 190, remaining portions of the spacer film 190 may be transformed into a spacer 195 on upper sidewalls of the first preliminary plug 84A and the second preliminary plug 88A.

The spacer 195 may surround the first preliminary plug 84A and the second preliminary plug 88A (see FIG. 3A). The spacer 195 may fill the region between the first preliminary plug 84A and the second preliminary plug 88A. The spacer 195 may be asymmetrically formed around the first preliminary plug 84A and the second preliminary plug 88A.

In an implementation, the spacer 195 may have different shapes in the side portions and the center portion of the first preliminary plug 84A and the second preliminary plug 88A. In another implementation, the spacer 195 may have the same shape in the side potions of the first preliminary plug 84A and the second preliminary plug 88A.

For example, the spacer 195 may have a profile similar to the first and second spacers 184 and 188 (see FIG. 6B), in the side potions of the first preliminary plug 84A and the second preliminary plug 88A. Thus, a lower surface of the spacer 195 may have the width W5 (see FIG. 3B), in the side portions of the first preliminary plug 84A and the second preliminary plug 88A.

The lower surface of the spacer 195 may have the width W6 between the first preliminary plug 84A and the second preliminary plug 88A. For example, the lower insulating film 40 may be recessed around the spacer 195. The upper surface of the lower insulating film 40 may have a step difference below and around the spacer 195.

Upper surfaces of the first preliminary plug 84A and the second preliminary plug 88A may be disposed at the height H1 (see FIG. 7A) from the lower insulating film 40, below the spacer 195. The upper surfaces of the first preliminary plug 84A and the second preliminary plug 88A may be disposed at a predetermined height H2 from the lower insulating film 40, around the spacer 195.

FIGS. 7C to 7E illustrate longitudinal sectional views showing stages in a method of forming a semiconductor device taken along lines VII-VII′, VIII-VIII′, and IX-IX′ of FIG. 3A according to an embodiment.

Referring to FIG. 7C, the first preliminary plug 84A and the second preliminary plug 88A (see FIG. 7B) may be partially removed using the lower insulating film 40 and the spacer 195 as an etching buffer film. By partially removing the first preliminary plug 84A and the second preliminary plug 88A, the first preliminary plug 84A and the second preliminary plug 88A may be recessed from an upper portion of the spacer 195, and remaining portions of the first preliminary plug 84A and the second preliminary plug 88A may be transformed into a first plug 84 and a second plug 88.

The spacer 195 may protrude from upper surfaces of the first plug 84 and the second plug 88 by a predetermined height H3. The first plug 84, the second plug 88, and the spacer 195 may have a positional relationship similar to the first plug 84, the second plug 88, the first spacer 94 and the second spacer 98 (see FIG. 5J). For example, the lower insulating film 40 may have a convex portion CVP and first concave portions CCP1 at an upper portion thereof.

The convex portion CVP, the first concave portions CCP1, and the spacer 195 may have a positional relationship similar to the convex portion CVP, the first concave portions CCP1, the first spacer 94, and the second spacer 98 (see FIG. 5J). For example, the lower insulating film 40 may not have the first concave portion CCP1 of the lower insulating film 40 between the first plug 84 and the second plug 88.

The lower insulating film 40 may have a first upper surface TS1 at the convex portion CVP, and second upper surfaces TS2 at the first concave portions CCP1. The first upper surface TS1 may be higher than the second upper surfaces TS2.

Referring to FIG. 7D, when the first plug 84 and the spacer 195 are viewed along line VIII-VIII′ of FIG. 3A, the spacer 195 may be symmetrically formed around the first plug 84. The first plug 84 and the spacer 195 may have a positional relationship similar to the first plug 84 and the first spacer 94 (see FIG. 5K). The lower insulating film 40 may have a shape similar to the lower insulating film 40 (see FIG. 5K), below and around the spacer 195.

Referring to FIG. 7E, when the lower insulating film 40 and the spacer 195 are viewed along line IX-IX′ of FIG. 3A, the lower insulating film 40 may have the convex portion CVP and the first concave portions CCP1, different from the lower insulating film 40 (see FIG. 5L). The spacer 195 may be disposed on the convex portion CVP of the lower insulating film 40.

FIG. 7F illustrates a longitudinal sectional view showing stages in a method of forming a semiconductor device taken along line VII-VII′ of FIG. 3A according to an embodiment.

Referring to FIG. 7F, process steps similar to those illustrated in FIGS. 5M to 5S may be used to form the lower insulating film 40. For example, each of first to third trenches 103, 106, and 109 may have the width D3 (see FIG. 6F). The second trench 106 may have a different shape from the second trench 106 of FIG. 5F. The second trench 106 may not extend into the lower insulating film 40.

For example, the spacer 195 may fill the region between the first and second plugs 84 and 88. A barrier film 120 and a conductive film 140 may be formed on an upper insulating film 100 to fill the first to third trenches 103, 106, and 109. Then, the first to third trenches 103, 106, and 109 may be filled with first to third interconnection lines 153, 156, and 159, respectively, by performing process steps similar to those illustrated in FIG. 5T.

The protection film 160 (see FIG. 3B) may be formed on the upper insulating film 100 and the first to third interconnection lines 153, 156, and 159. The protection film 160 may be included in the semiconductor device 223, together with the first and second plugs 84 and 88, the spacer 195, and the first to third interconnection lines 153, 156, and 159. The second concave portions CCP2 may be below the first and second interconnection lines 153 and 156 in the upper portion of the lower insulating film 40 (see FIGS. 3C and 3D). Thus, the semiconductor device 223 may generate or achieve the same effects as the semiconductor device 221 of FIG. 1A.

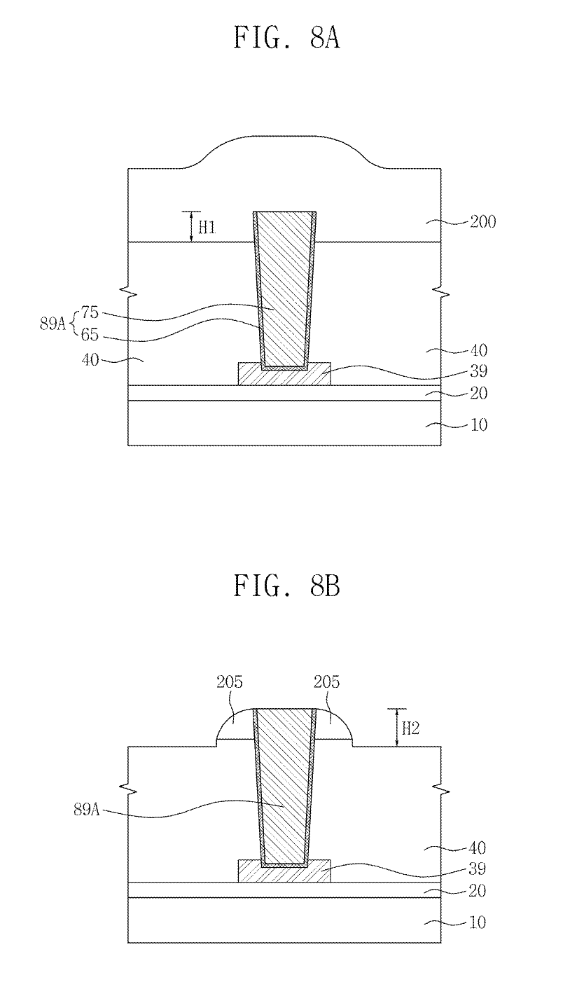

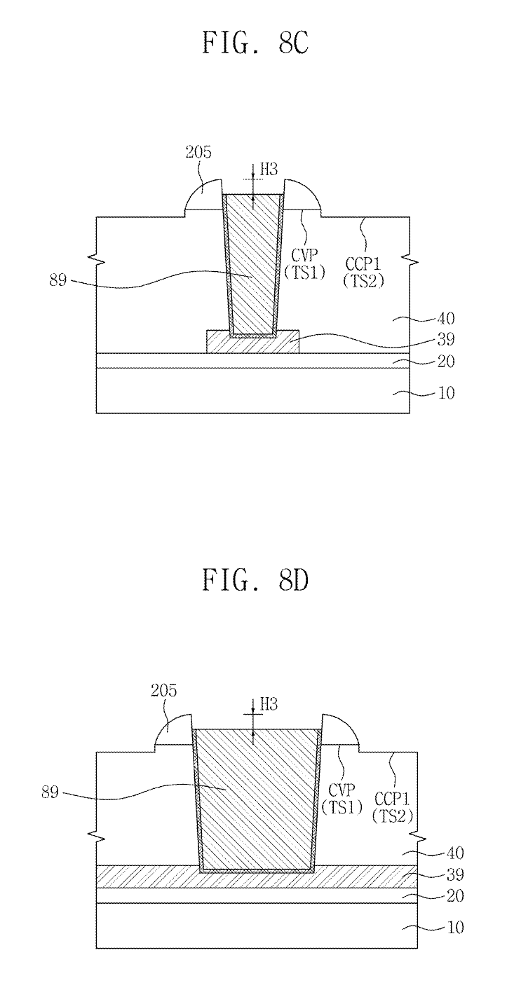

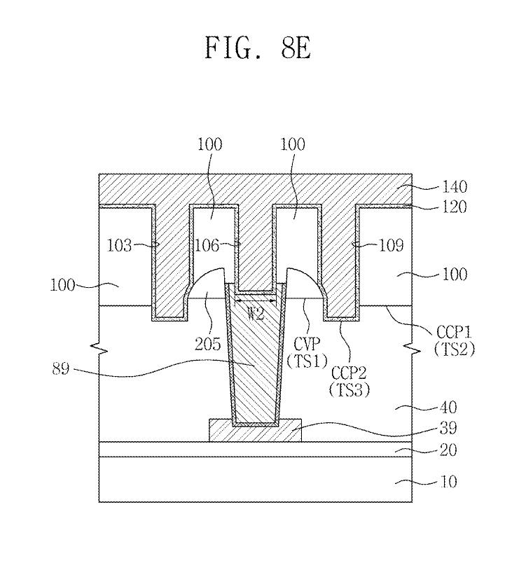

Next, a method of forming a semiconductor device according to still another embodiment will be described by referring to FIGS. 8A to 8E. In FIGS. 8A to 8E, the same reference numerals are used to denote the same components as in FIGS. 5A to 5T.

FIGS. 8A and 8B illustrate longitudinal sectional views showing stages in a method of forming a semiconductor device taken along line X-X′ of FIG. 4A according to an embodiment.

Referring to FIG. 8A, a landing pattern 39 may be formed on the material film 20. Process steps similar to those illustrated in FIGS. 5A to 5G may be used to form the landing pattern 39 and the material film 20. For example, the first photoresist film 50 may have one of the first and second openings 54 and 58. Thus, one preliminary plug 89A (corresponding to the one opening) may be formed on the landing patterns 39, as shown in FIG. 8A.

The preliminary plug 89A may include the same material as or a different material from the first and second preliminary plugs 84A and 88A (see FIG. 5F). The preliminary plug 89A may protrude from a lower insulating film 40 by the height H1 (see FIG. 5G). A spacer film 200 may be formed on the lower insulating film 40 and the preliminary plug 89A. The spacer film 200 may be formed along the protruded shape of the preliminary plug 89A from the lower insulating film 40.

The spacer film 200 may include the same material as or a different material from the spacer film 90 of FIG. 5H. The spacer film 200 may be formed using a chemical vapor deposition technique or a physical deposition technique.

Referring to FIG. 8B, portions of the spacer film 200 of FIG. 8A may be removed to expose the lower insulating film 40 and the preliminary plug 89A. The portions of the spacer film 200 may be removed using a dry etching technique. By removing the portions of the spacer film 200, remaining portions of the spacer film 200 may be transformed into a spacer 205 on an upper sidewall of the preliminary plug 89A. The spacer 205 may surround the preliminary plug 89A (see FIG. 4A).

The spacer 205 may be symmetrically formed at side portions of the preliminary plug 89A. A lower surface of the spacer 205 may have the width W7 (see FIG. 4B). In an implementation, the lower insulating film 40 may be recessed around the spacer 205. A lower surface of the lower insulating film 40 may have a step difference below and around the spacer 205.

An upper surface of the preliminary plug 89A may be disposed at the height H1 (see FIG. 8A) from the lower insulating film 40, below the spacer 205. The upper surface of the one preliminary plug 89A may be disposed at a predetermined height H2 from the lower insulating film 40, around the spacer 205.

FIGS. 8C and 8D illustrate longitudinal sectional views showing stages in a method of forming a semiconductor device taken along lines X-X′, and XI-XI′ of FIG. 4A according to an embodiment.

Referring to FIG. 8C, the one preliminary plug 89A may be partially removed using the lower insulating film 40 and the spacer 205 as an etching buffer film. By removing portions of the one preliminary plug 89A, the one preliminary plug 89A may be recessed from an upper portion of the spacer 205, and remaining portions may be transformed into a plug 89. The spacer 205 may protrude from the plug 89 by a predetermined height H3.

The plug 89 and the spacer 205 may have a positional relationship similar to the first plug 84, the second plug 88, the first spacer 94 and the second spacer 98 (see FIG. 5J). In an implementation, the lower insulating film 40 may have a convex portion CVP and first concave portions CCP1 at an upper portion thereof.

The convex portion CVP, the first concave portions CCP1, and the spacer 205 may have a positional relationship similar to the convex portion CVP, the first concave portions CCP1, the first spacer 94, and the second spacer 98 (see FIG. 5J). In an implementation, the lower insulating film 40 may not have the first concave portion CCP1 between the first spacer 94 and the second spacer 98 (see FIG. 5J).

The lower insulating film 40 may have a first upper surface TS1 at the convex portion CVP and second upper surfaces TS2 at the first concave portion CCP1. The first upper surface TS1 may be higher than the second upper surfaces TS2.

Referring to FIG. 8D, when the plug 89 and the spacer 205 are viewed along line XI-XI′ of FIG. 4A, the spacer 205 may be symmetrically formed at the side portions of the plug 89. The plug 89 and the spacer 205 may have a positional relationship similar to the first plug 84 and the first spacer 94 (see FIG. 5K). The lower insulating film 40 may have a similar shape to the lower insulating film 40 of FIG. 5K, below and around the spacer 205.

FIG. 8E illustrates a longitudinal sectional views showing stages in a method of forming a semiconductor device taken along line X-X′ of FIG. 4A according to an embodiment.

Referring to FIG. 8E, process steps similar to those illustrated in FIGS. 5M to 5S may be used to form the lower insulating film 40. In an implementation, each of first to third trenches 103, 106, and 109 may have the width D3 (see FIG. 6F) on the plug 89 and/or in an upper insulating film 100. The first to third trenches 103, 106, and 109 may have a different shape from the first to third trenches 103, 106, and 109 of FIG. 5P.

For example, the first trench 103 and the third trench 109 may penetrate the upper insulating film 100 to extend into the lower insulating film 40. Lower surfaces of the first trench 103 and the third trench 109 may be at third upper surfaces TS3 of second concave portions CCP2 of the lower insulating film 40. The first trench 103 and the third trench 109 may expose the spacer 205. The second trench 106 may penetrate the upper insulating film 100 to extend into the plug 89.

A barrier film 120 and a conductive film 140 may be formed on the upper insulating film 100 to fill the first to third trenches 103, 106, and 109. Then, the first to third trenches 103, 106, and 109 may be filled with the first to third interconnection lines 153, 156, and 159 by using process steps similar to those illustrated in FIG. 5T.

The protection film 221 (see FIG. 4B) may be formed on the upper insulating film 100 and the first to third interconnection lines 153, 156, and 159. The protection film 160 may be included in the semiconductor device 224, together with the plug 89, the spacer 205, and the first to third interconnection lines 153, 156, and 159. The semiconductor device 224 may generate a similar effect as the semiconductor device 221 of FIG. 1A.

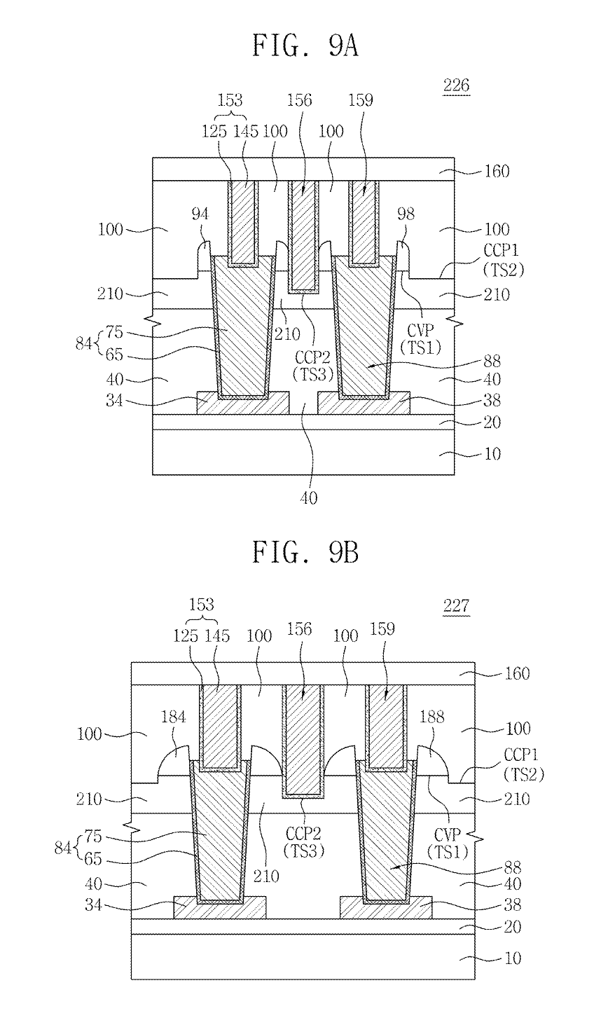

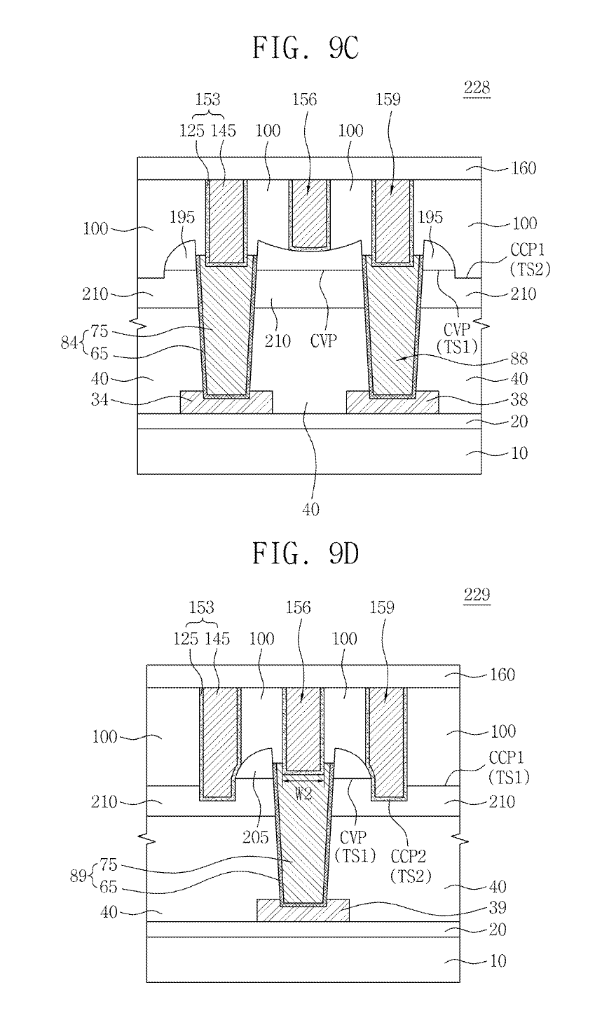

FIG. 9A illustrates a longitudinal sectional view of a semiconductor device according to an embodiment. In FIG. 9A, the same reference numerals are used to denote the same components as in FIGS. 5A to 5T.

Referring to FIG. 9A, a semiconductor device 226 may use an arrangement structure similar to the semiconductor device 221 (see FIG. 1B). The semiconductor device 226 may include an etching stop film 210 between a lower insulating film 40 and an upper insulating film 100. The etching stop film 210 may include an insulating material, e.g., silicon oxide or silicon nitride. The etching stop film 210 may have an etching rate different from those of the lower insulating film 40 and the upper insulating film 100.

In an implementation, the lower insulating film 40 and the upper insulating film 100 may include a porous material structure. Thus, the etching stop film 210 may include a relatively dense material structure, as compared with the lower insulating film 40 and the upper insulating film 100. For example, the lower insulating film 40 may include a SiOCH material (having a dielectric constant less than 3.0) and the etching stop film 210 may include a high density plasma (HDP) oxide.

The etching stop film 210 may have a similar upper surface to the lower insulating film 40 (see FIGS. 1B, 1C, and 1D). Thus, lower surfaces of first to third interconnection lines 153, 156, and 159 in the semiconductor device 226 may be uniformly disposed between a first upper surface TS1 of a convex portion CVP and a lower surface of the etching stop film 210, except for upper surfaces of first and second plugs 84 and 88. As a result, the second interconnection line 156 may be uniformly spaced apart from the first and second plugs 84 and 88 by using first and second spacers 94 and 98 and the etching stop film 210.

FIG. 9B illustrates a longitudinal sectional view of a semiconductor device according to an embodiment. In FIG. 9B, the same reference numerals are used to denote the same components as in FIGS. 5A to 5T, and 9A.

Referring to FIG. 9B, a semiconductor device 227 according to the present embodiment may use an arrangement structure similar to the semiconductor device 222 (see FIG. 2B). The semiconductor device 227 may include an etching stop film 210 between a lower insulating film 40 and an upper insulating film 100. The etching stop film 210 may have a similar upper surface to the lower insulating film 40 (see FIGS. 2B, 2C, and 2D).

Lower surfaces of first to third interconnection lines 153, 156, and 159 in the semiconductor device 227 may be uniformly disposed between a first upper surface TS1 of a convex portion CVP and a lower surface of the etching stop film 210, except for upper surfaces of first and second plugs 84 and 88. As a result, the semiconductor device 227 may have the second interconnection line 156, which may be uniformly spaced apart from the first and second plugs 84 and 88 using a first spacer 184, a second spacer 188 and the etching stop film 210.

FIG. 9C illustrates a longitudinal sectional view of a semiconductor device according to an embodiment. In FIG. 9C, the same reference numerals are used to denote the same components as in FIGS. 5A to 5T, and 9A.

Referring to FIG. 9C, a semiconductor device 228 according to the present embodiment may use an arrangement structure similar to the semiconductor device 223 (see FIG. 3B). The semiconductor device 228 may include an etching stop film 210 between a lower insulating film 40 and an upper insulating film 100. The etching stop film 210 may have a similar upper surface to the lower insulating film 40 (see FIGS. 3B, 3C, and 3D).

Lower surfaces of first to third interconnection lines 153, 156, and 159 in the semiconductor device 228 may be uniformly disposed between a first upper surface TS1 of a convex portion CVP and a lower surface of the etching stop film 210, except for upper surfaces of first and second plugs 84 and 88.

FIG. 9D illustrates a top view or a plan view of a semiconductor device according to an embodiment. In FIG. 9D, the same reference numerals are used to denote the same components as in FIGS. 5A to 5T, and 9A.

Referring to FIG. 9D, a semiconductor device 229 according to the present embodiment may use an arrangement structure similar to the semiconductor device 224 (see FIG. 4B). The semiconductor device 229 may include an etching stop film 210 between a lower insulating film 40 and an upper insulating film 100. The etching stop film 210 may have a similar upper surface to the lower insulating film 40 of FIGS. 4B and 4C.

Lower surfaces of first to third interconnection lines 153, 156, and 159 in the semiconductor device 229 may be uniformly disposed between a first upper surface TS1 of a convex portion CVP and a lower surface of the etching stop film 210, except for upper surfaces of first and second plugs 84 and 88. As a result, the semiconductor device 229 may have the first and third interconnection lines 153 and 159, which may be uniformly spaced apart from the plug 89 by using the spacer 205 and the etching stop film 210.

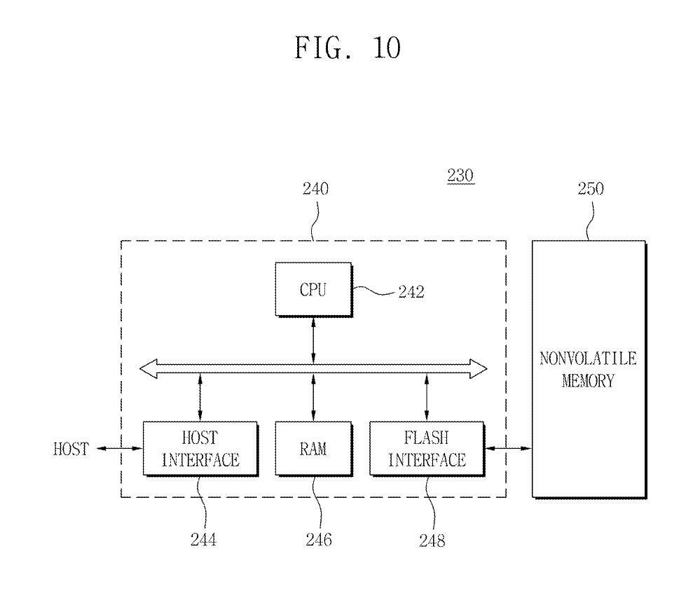

FIG. 10 illustrates an electronic system including a semiconductor device according to an embodiment.

Referring to FIG. 10, an electronic system 230 according to the present embodiment may include a memory controller 240 and a memory device 250. The memory controller 240 may include a central processing unit (CPU) 242, a host interface 244, a RAM 226, and a flash interface 248. The memory device 250 may include one of the semiconductor devices 221 to 224 of FIGS. 1A, 2A, 3A, and 4A.

The memory device 250 may include one of the semiconductor devices 226 to 229 of FIGS. 9A to 9D.

By way of summation and review, a semiconductor device may include plugs, interconnection lines, and an insulating film. The plugs and the interconnection lines may have conductivity. The plug may be disposed around and/or under the interconnection lines. The interconnection lines may contact the plugs and may be disposed adjacent to the plugs. The insulating film may be located between the plugs and the interconnection lines and may electrically insulate the plugs and the interconnection lines.

As the degree of integration of the semiconductor device increases, a distance and an align margin between the plugs and the interconnection lines may be reduced. Thus, the insulating film may not sufficiently insulate the plugs and the interconnection lines and the plugs and the interconnection lines may electrically connect through the insulating film.

The distance and the align margin between the plugs and the interconnection lines may be increased by including a lower oxide layer, a nitride layer and an upper oxide layer in the insulating film. The insulating film may have the plugs in the lower oxide layer, and the interconnection lines in the nitride layer and the upper oxide layer.

The nitride layer may be disposed along the interconnection lines and may increase a parasitic capacitance between the plugs and/or the interconnection lines. Also, the insulating film may have the plugs in the lower oxide layer, and the interconnection lines on the nitride layer and in the upper oxide layer. Accordingly, the nitride layer may cause a difference of volume between a part of the interconnection lines contacting the plugs, and the remaining interconnection lines around the plugs.

As a result, the semiconductor device may have increased parasitic capacitance and a difference of volume of the interconnection lines on and/or around the plugs, and may have a deteriorated operation velocity owing to the foregoing.

With respect to the foregoing detailed description and the drawings, an element not having a reference numeral or having only the reference numeral in a figure may easily be understood as a name or a function through illustration of other figures.

As described above, an embodiment provides a semiconductor device, which includes a spacer surrounding an upper sidewall of a plug. The spacer may prevent a short circuit between the plug and an interconnection line around the plug.

An example also provides a semiconductor device, which includes a ring-shaped spacer disposed only around a plug, thereby reducing the parasitic capacitance between the plug and a neighboring interconnection line on the plug.

Further, an embodiment provides a semiconductor device suitable for reducing resistance of an interconnection line by forming the volume of the interconnection line in different sizes on and around a plug.

Furthermore, an embodiment provides a semiconductor device, which enhances operation speed thereof by reducing the resistance of a single interconnection line and the parasitic capacitance between a plug and a neighboring interconnection line to the plug.

In addition, the embodiments provide a semiconductor device that helps prevent a short circuit between a plug and an interconnection line adjacent to the plug.

While the embodiments have been particularly shown and described with reference to example embodiments thereof, it will be understood by those skilled in the art that various changes in form and details may be made therein without departing from the spirit and scope of the inventive concepts as defined by the appended claims.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a plug;
a lower insulating film surrounding a lower sidewall of the plug;
a spacer surrounding an upper sidewall of the plug; and
a first interconnection line on the plug, the lower insulating film, and the spacer, the first interconnection line being in contact with an upper surface of the plug,
wherein an upper portion of the spacer protrudes higher than the upper surface of the plug.

2. The semiconductor device as claimed in claim 1, wherein the lower insulating film is below the spacer, the lower insulating film including a first upper surface lower than the upper surface of the plug.

3. The semiconductor device as claimed in claim 2, wherein the lower insulating film is aligned with a sidewall of the spacer, the lower insulating film including a second upper surface lower than the first upper surface.

4. The semiconductor device as claimed in claim 3, wherein the first interconnection line includes a first lower surface on the plug, the first lower surface being lower than an uppermost surface of the plug.

5. The semiconductor device as claimed in claim 4, wherein the first lower surface of the first interconnection line is higher than the second upper surface of the lower insulating film.

6. The semiconductor device as claimed in claim 4, wherein the first interconnection line includes a second lower surface lower than the first lower surface thereof, the second lower surface being on the second upper surface of the lower insulating film.

7. The semiconductor device as claimed in claim 4, further comprising a second interconnection line at an exterior of the spacer, the second interconnection line extending horizontally in parallel with the first interconnection line.

8. The semiconductor device as claimed in claim 7, wherein the second interconnection line is in contact with the spacer.

9. The semiconductor device as claimed in claim 7, wherein the second interconnection line includes a lower surface, the lower surface of the second interconnection line being lower than the second upper surface of the lower insulating film.

10. The semiconductor device as claimed in claim 1, wherein:
the plug has a vertically extending pillar shape, and
the first interconnection line has a horizontally extending line shape.

11. The semiconductor device as claimed in claim 1, wherein the spacer has a ring shape when viewed in a plan view.

12. The semiconductor device as claimed in claim 11, wherein the first interconnection line is in contact with an upper portion of the spacer and intersects the spacer.

13. The semiconductor device as claimed in claim 11, wherein the spacer includes:
a lower spacer sidewall in contact with the plug, and
an upper spacer sidewall not contacting the plug.

14. A semiconductor device, comprising:
a plug;
a lower insulating film covering a lower sidewall of the plug;
a spacer covering an upper sidewall of the plug; and
an interconnection line on the plug, the lower insulating film, and the spacer,
wherein:
the interconnection line includes a first boundary surface, a second boundary surface, and a third boundary surface at a lower surface thereof,
the first boundary surface is at an interface of an upper portion of the spacer and the lower surface of the interconnection line,
the second boundary surface is at an interface of an upper surface of the plug and the lower surface of the interconnection line,
the third boundary surface is at an interface of an upper surface of the lower insulating film and the lower surface of the interconnection line,
the first boundary surface is higher than the second boundary surface, and
the second boundary surface is higher than the third boundary surface.

15. The semiconductor device as claimed in claim 14, further comprising a fourth boundary surface at an interface of a lower surface of the spacer and the upper surface of the lower insulating film, the fourth boundary surface being lower than the second boundary surface and higher than the third boundary surface.

16. A semiconductor device, comprising:
a plug having a lower sidewall and an upper sidewall;
a lower insulating film surrounding the lower sidewall of the plug;
a spacer surrounding the upper sidewall of the plug; and
a first interconnection line on the plug, the lower insulating film, and the spacer, the first interconnection line being in contact with a surface of the plug,
wherein:
an uppermost portion of the spacer protrudes higher than an uppermost surface of the plug,
the first interconnection line has a first lower surface on the plug,
the lower insulating film has a first upper surface on a lower spacer surface of the spacer, and
a plane of the first lower surface is between a plane of the first upper surface of the lower insulating film and a plane of the uppermost surface of the plug.

17. The semiconductor device as claimed in claim 16, wherein the lower insulating film is aligned with a sidewall of the spacer, the lower insulating film including a second upper surface lower than the first upper surface.

18. The semiconductor device as claimed in claim 17, further comprising a second interconnection line at an exterior of the spacer, the second interconnection line extending horizontally in parallel with the first interconnection line.

19. The semiconductor device as claimed in claim 18, wherein the second interconnection line includes a lower second interconnection line surface, a plane of the lower second interconnection line surface being lower than a plane of the second upper surface of the lower insulating film.

20. The semiconductor device as claimed in claim 16, wherein the spacer has a ring shape when viewed in a plan view, the spacer including:
a lower spacer sidewall in contact with the plug, and
an upper spacer sidewall not contacting the plug.
